(19) United States
(12) Patent Application Publication
(10) Pub. No.: US 2019/0087523 A1
(43) Pub. Date: Mar. 21, 2019

(54) PROGRAMMABLE INTEGRATED CIRCUIT, CALCULATION SYSTEM, BIT STRING GENERATING DEVICE, CONTROL METHOD OF PROGRAMMABLE INTEGRATED CIRCUIT, AND BIT STRING GENERATION METHOD

(71) Applicants: Kabushiki Kaisha Toshiba, Tokyo (JP); Toshiba Electronic Devices & Storage Corporation, Tokyo (JP)

(72) Inventors: Kazuki Inoue, Kawasaki Kanagawa (JP); Kohei Oikawa, Kawasaki Kanagawa (JP)

(21) Appl. No.: 15/908,257

(22) Filed: Feb. 28, 2018

(30) Foreign Application Priority Data
Sep. 15, 2017 (JP) 2017-177983

(51) Int. Cl. G06F 17/50; G11C 16/10; G11C 29/12; G11C 13/00; G11C 11/16

(52) U.S. Cl. CPC G06F 17/5054; G11C 16/10; G11C 11/16; G11C 13/0002; G11C 29/12

(57) ABSTRACT

According to one embodiment, a programmable integrated circuit includes a circuit group including a plurality of physical modules, a configuration memory that stores a configuration bit string indicating a physical module to be allocated to each of one or more operation contents in a circuit configuration implemented by the circuit group among the plurality of physical modules, a changing circuit that changes at least part of the allocation of the physical module to the operation content so that exhaustion degrees of a plurality of memory cells constituting the configuration memory are equalized, and a configuration memory access circuit that stores a configuration bit string indicating the changed allocation in the configuration memory.

### CROSS-REFERENCE TO RELATED APPLICATIONS

This application is based upon and claims the benefit of priority from Japanese Patent Application No. 2017-177983, filed on Sep. 15, 2017; the entire contents of all of which are incorporated herein by reference.

### FIELD

Embodiments described herein relate generally to a programmable integrated circuit, a calculation system, a bit string generating device, a control method of a programmable integrated circuit, and a bit string generation method.

### BACKGROUND

In recent years, a field programmable gate array (FPGA) which is capable of flexibly rewriting a circuit configuration has attracted attention in fields such as data center and Internet of things (IoT). In this regard, there is a demand for a large-capacity FPGA having low power consumption.

### BRIEF DESCRIPTION OF THE DRAWINGS

FIG. 1 is a block diagram illustrating a schematic configuration example of an FPGA according to a first embodiment;

FIG. 2 is a diagram illustrating a schematic configuration example of a wiring module illustrated in FIG. 1;

FIG. 3 is a schematic diagram illustrating a schematic configuration example of an external configuration of generating a configuration bit string according to the first embodiment;

FIG. 4 is a flowchart illustrating an example of a configuration bit generation operation executed in a bit string generating device illustrated in FIG. 3;

FIG. 5 is a block diagram illustrating a schematic configuration example of the FPGA according to the first embodiment;

FIG. 6 is a diagram illustrating an example of a circuit configuration implemented in a circuit group in accordance with a non-changed configuration bit string in the first embodiment;

FIG. 7 is a diagram illustrating an example of a circuit configuration implemented in a circuit group in accordance with a changed configuration bit string in the first embodiment;

FIG. 8 is a diagram illustrating an example of a connection path formed in a wiring module in accordance with a non-changed configuration bit string in the first embodiment;

FIG. 9 is a diagram illustrating an example of a connection path formed in a wiring module by a configuration bit string changed in accordance with a certain rule in the first embodiment;

FIG. 10 is a block diagram illustrating a schematic configuration example of an FPGA according to a second embodiment;

FIG. 11 is a flowchart illustrating an example of a configuration bit changing operation in the second embodiment;

FIG. 12 is a block diagram illustrating a schematic configuration example of an FPGA according to a third embodiment;

FIG. 13 is a diagram for describing an example in which a circuit group is divided into a plurality of partial regions in the third embodiment;

FIG. 14 is a diagram illustrating an example of a region of a use circuit resource before change in the third embodiment;

FIG. 15 is a diagram illustrating an example of a region of a use circuit resource after change in the third embodiment;

FIG. 16 is a flowchart illustrating an example of a configuration bit changing operation in the third embodiment;

FIG. 17 is a diagram illustrating another example of a region of a use circuit resource after change in the third embodiment;

FIG. 18 is a block diagram illustrating a schematic configuration example of an FPGA according to a fourth embodiment;

FIG. 19 is a block diagram illustrating a schematic configuration example of a modified example of an FPGA according to the fourth embodiment;

FIG. 20 is a schematic diagram illustrating a schematic configuration example of an external configuration of generating a configuration bit string according to a fifth embodiment;

FIG. 21 is a block diagram illustrating a schematic configuration example of an FPGA according to the fifth embodiment;

FIG. 22 is a flowchart illustrating a specific example of an arrangement process in the fifth embodiment;

FIG. 23 is a flowchart illustrating a specific example of an arrangement process in a sixth embodiment;

FIG. 24 is a flowchart illustrating a specific example of an arrangement process in a seventh embodiment;

FIG. 25 is a flowchart illustrating a specific example of a wiring process in an eighth embodiment;

FIG. 26 is a flowchart illustrating a specific example of a wiring process in a ninth embodiment;

FIG. 27 is a diagram for describing a change in a wiring path in a tenth embodiment;

FIG. 28 is a block diagram illustrating a schematic configuration example of an FPGA according to an eleventh embodiment;

FIG. 29 is a block diagram illustrating a schematic configuration example of an FPGA according to a twelfth embodiment;

FIG. 30 is a block diagram illustrating a schematic configuration example of an FPGA according to a thirteenth embodiment;

FIG. 31 is a block diagram illustrating a schematic configuration example of a modified example of the FPGA according to the thirteenth embodiment; and

FIG. 32 is a block diagram illustrating a schematic configuration example of a calculation system according to a fifteenth embodiment.

### DETAILED DESCRIPTION

In general, according to one embodiment, a programmable integrated circuit includes a circuit group including a plurality of physical modules, a configuration memory that stores a configuration bit string indicating a physical module to be allocated to each of one or more operation contents in a circuit configuration implemented by the circuit group among the plurality of physical modules, a changing circuit that changes at least part of the allocation of the physical module to the operation content so that exhaustion degrees of a plurality of memory cells constituting the configuration memory are equalized, and a configuration memory access circuit that stores a configuration bit string indicating the changed allocation in the configuration memory, wherein the physical module is associated with any one of the plurality of memory cells in a one-to-one manner, each bit of the configuration bit string corresponds to any one of the plurality of physical modules in a one-to-one manner, and each memory cell of the configuration memory stores one bit of the configuration bit string.

Exemplary embodiments of a programmable integrated circuit, a calculation system, a bit string generating device, a control method of a programmable integrated circuit, and a bit string generation method will be described in detail below with reference to the appended drawings. The present invention is not limited by the following embodiments.

As a method of implementing a large-capacity FPGA having low power consumption which is one of programmable integrated circuits, for example, it is considered to use a non-volatile memory such as a magnetoresistive random access memory (RAM) (MRAM) or a resistive RAM (ReRAM) as a storage element. Such non-volatile memories have an advantageous in that it is possible to implement the larger capacity and the lower power consumption than SRAMs and hold data in a non-volatile state.

However, general non-volatile memories are lower in durability (the number of programs/erases or the like) than SRAMs. Therefore, if the non-volatile memory is used as the storage element of the FPGA, the product lifespan of the FPGA is likely to be shorter than in a case in which the SRAM is used.

In this regard, in the following embodiments, a programmable integrated circuit capable of improving the product lifespan will be described with several examples. The embodiments to be described below are effective not only for non-volatile memories but also for volatile memories. Further, an FPGA architecture is not limited to architectures to be described below.

### First Embodiment

In a first embodiment, in order to improve the product lifespan of the FPGA, information for implementing a desired circuit configuration in an FPGA (hereinafter referred to as “circuit information”) is converted randomly or in accordance with a predetermined rule. Accordingly, a physical module different from a previous one is used each time a circuit configuration of an FPGA is rewritten, and thus the same physical module is prevented from being intensively used. As a result, an exhaustion degree is equalized in all physical modules and all storage elements (hereinafter referred to simply as “memory cells”) associated with the respective physical module, and thus it is possible to improve the product lifespan of the FPGA. Here, the physical modules are structural elements, such as the following wiring modules 104 and the following operation modules 105, for implementing a desired circuit configuration in an FPGA.

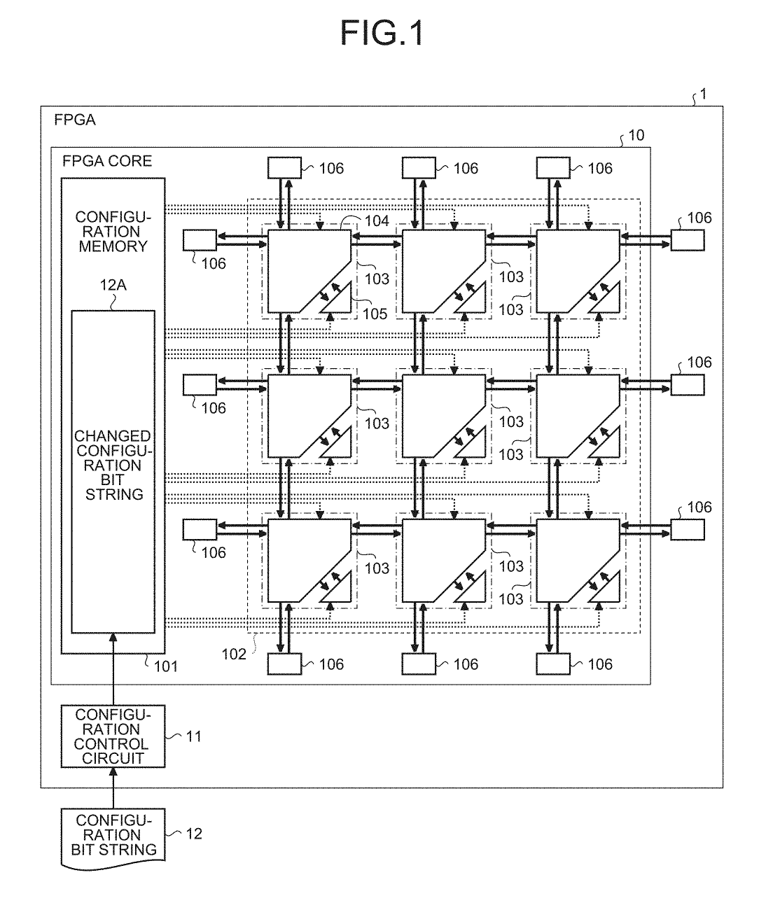

FIG. 1 is a block diagram illustrating a schematic configuration example of an FPGA according to a first embodiment. As illustrated in FIG. 1, an FPGA 1 includes an FPGA core 10 capable of dynamically changing a circuit configuration and a configuration control circuit 11 that controls a circuit configuration implemented by the FPGA core 10.

Configuration bits (hereinafter referred to as a “configuration bit string”) 12 generated by an external bit string generating device 301 such as a personal computer (hereinafter referred to as a “PC”) are input to the configuration control circuit 11. The configuration bit string 12 is, for example, binary data including a plurality of configuration bits indicated by ‘0’ or ‘1’ and serves as circuit information designating an wiring module 104 and an operation module 105 used in a circuit group 102.

The configuration control circuit 11 converts the bit array, bit values, or the like of the input configuration bit string 12, for example, randomly or in accordance with a predetermined rule and inputs a configuration bit string obtained accordingly (hereinafter referred to as a “changed configuration bit string”) 12A to the FPGA core 10.

The FPGA core 10 includes a configuration memory 101 and the circuit group 102. The configuration memory 101 stores the changed configuration bit string 12A input from the configuration control circuit 11. The circuit group 102 includes a plurality of basic modules 103 arranged in a two-dimensional array form, and each of the basic modules 103 includes, for example, one wiring module 104 and one operation module 105.

The operation module 105 is a module that performs a logical operation and executes an operation process on a signal input from the wiring module 104 in the same basic module 103 and outputs a result obtained accordingly to the wiring module 104.

The wiring module 104 is a module that dynamically changes a connection relation with other basic modules 103 or input/output terminals 106 that are adjacent on the left, right, top, and bottom thereof and are connected via the input/output terminals 106 connected to the wiring module 104 in the adjacent basic module 103 or an external circuit and one or more bundles of wirings (hereinafter referred to as “channels”). Further, the wiring module 104 dynamically changes a connection with the operation module 105 in the same basic module 103 as well.

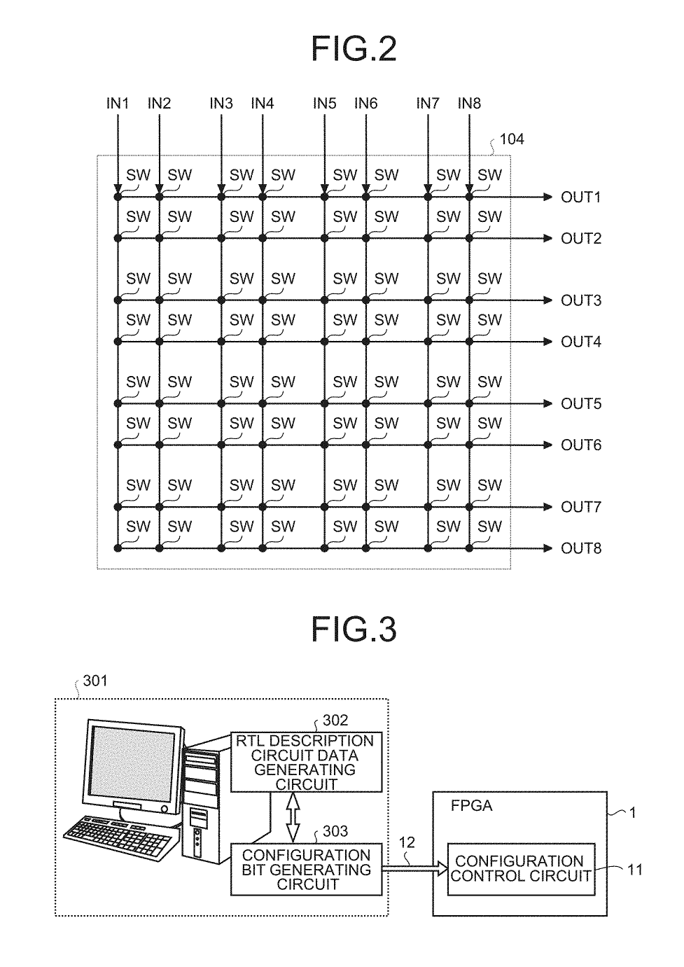

Here, a schematic configuration example of the wiring module 104 is illustrated in FIG. 2. For example, as illustrated in FIG. 2, the wiring module 104 has a structure in which a plurality of input wirings IN1 to IN8 and a plurality of output wirings OUT1 to OUT8 cross each other in a grid form. A switch SW that turns on/off the connection between each of the input wirings IN1 to IN8 and each of the output wirings OUT1 to OUT8 is disposed at each of the crossing portions of the input wirings IN1 to IN8 and the output wirings OUT1 to OUT8. Therefore, it is possible to switch a path from an input of a signal to an output thereof in the wiring module 104 by turning each switch SW on or off.

Each of the input wirings IN1 to IN8 is connected to any one of the input/output terminal 106 (see FIG. 1), one of the output wirings OUT1 to OUT8 of the wiring module 104 in the adjacent basic module 103, and the operation module 105 in the same basic module 103. Similarly, each of the output wirings OUT1 to OUT8 is connected to any one of the input/output terminal 106, one of the input wirings IN1 to IN8 of the wiring module 104 in the adjacent basic module 103, or the operation module 105 in the same basic module 103.

The on/off state of each switch SW in the wiring module 104 is controlled in accordance with the bit information (the changed configuration bit string 12A) in the configuration memory 101. In other words, each switch SW is associated with each memory cell in the configuration memory 101 in a one-to-one manner. Therefore, it is possible to change the circuit configuration implemented in the circuit group 102 by rewriting the changed configuration bit string 12A stored in the configuration memory 101.

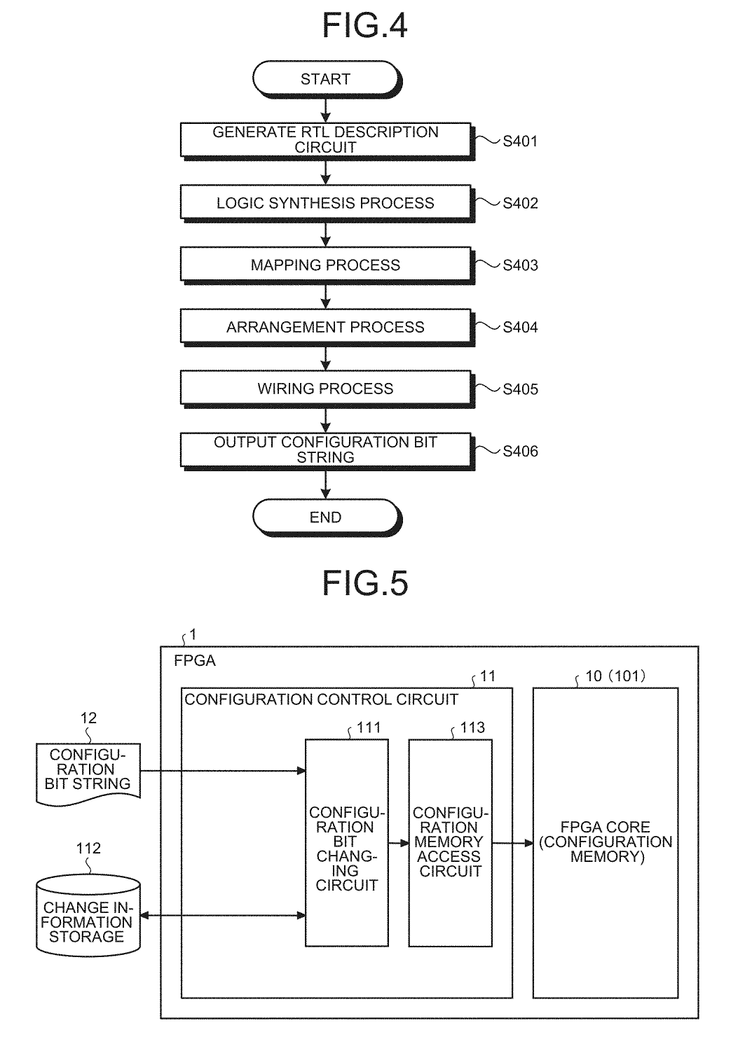

FIG. 3 is a schematic diagram illustrating a schematic configuration example of an external configuration of generating a configuration bit string according to the present embodiment. FIG. 4 is a flowchart illustrating an example of a configuration bit generation operation executed in the bit string generating device illustrated in FIG. 3.

As illustrated in FIG. 3, the configuration bit string 12 is generated using the bit string generating device 301 such as a personal computer (hereinafter referred to as a “PC”). The bit string generating device 301 includes, for example, a register transfer level (RTL) description circuit data generating circuit 302 and a configuration bit generating circuit 303.

As illustrated in FIG. 4, the RTL description circuit data generating circuit 302 generates circuit information in which a desired circuit configuration is described at an RTL (hereinafter referred to as an “RTL description circuit”), for example, on the basis of input from a user (Step S401). Then, the configuration bit generating circuit 303 sequentially executes a logic synthesis process of converting the RTL description circuit into a gate level description by following a predetermined electronic design automation (EDA) flow (Step S402) and a mapping process for converting circuit information which has undergone the logic synthesis into a network of operation module level (Step S403) and then sequentially executes an arrangement process of deciding an allocation of the physical operation module 105 (also referred to as a “circuit resource”) on the basis of a result of the mapping process (Step S404) and a wiring process of deciding a physical wiring path between the operation modules 105 (for example, the wiring module 104, hereinafter referred to as a “wiring resource”) (Step S405). Thereafter, the configuration bit generating circuit 303 outputs the configuration bit string 12 obtained as a result of the EDA flow (Step S406), and ends the present operation.

The configuration bit string 12 generated as described above is input to the configuration control circuit 11 of the FPGA 1 via a predetermined network or a removable medium. The configuration control circuit 11 generates the changed configuration bit string 12A by converting the input configuration bit string 12, for example, randomly or in accordance with a predetermined rule in advance, and stores the generated changed configuration bit string 12A in the configuration memory 101.

Here, as the predetermined rule, for example, various rules such as a rule of switching an even number and an odd number in the bit array of the configuration bit string 12, a rule of shifting one or more bit arrays of the configuration bit string 12 input each time the changed configuration bit string 12A in the configuration memory 101 is rewritten in a predetermined direction, and a rule of deciding a shift target bit and a shift amount on the basis of content of change previously performed on the configuration bit string 12 (hereinafter referred to as “previous change information”) can be employed.

In order to prevent signal collision, for example, a restriction that a plurality of switch SWs are not turned on in an output line (for example, corresponding to the output wirings OUT1 to OUT8 in FIG. 2) in an overlapping manner may be set in a predetermined rule for changing the configuration bit string 12. Further, in order to prevent a significant change in a signal delay, a restriction that output directions of signals from the respective basic modules 103 (for example, corresponding to the up, down, left, and right direction with respect to each basic module 103 in FIG. 1) does not change may be set.

FIG. 5 is a block diagram illustrating a schematic configuration example of the FPGA according to the present embodiment, focused on a configuration example of the configuration control circuit. As illustrated in FIG. 5, the configuration control circuit 11 includes a configuration bit changing circuit 111 and a configuration memory access circuit 113. In addition to this, an error correction code (ECC) circuit, an encryption circuit, a debugging circuit, and the like may be incorporated in the FPGA 1.

The configuration bit string 12 input to the configuration control circuit 11 is input to the configuration bit changing circuit 111. The configuration bit changing circuit 111 generates a new changed configuration bit string 12A by converting the bit configuration of the input configuration bit string 12 randomly or in accordance with a predetermined rule. The configuration memory access circuit 113 stores the changed configuration bit string 12A generated by the configuration bit changing circuit 111 in the configuration memory 101 of the FPGA core 10.

Content of the change executed on configuration bit string 12 by the configuration bit changing circuit 111 (such as a rule used for the change, position information of a changed bit, or the like) is accumulated in a change information storage 112 as change information. The change information storage 112 may be physically installed in a storage region provided in the FPGA 1 or may be physically installed in a storage region outside the FPGA 1. The configuration bit changing circuit 111 can specify the change which has been previously executed on the same or different configuration bit string 12 with reference to the change information storage 112. Further, when the bit configuration of the configuration bit string 12 is changed randomly, it is also possible to omit the change information storage 112.

The change information may include at least one of the number of uses of each memory cell in the configuration memory 101 (the number of programs/erases, or the like), information specifying the circuit resource used by the changed configuration bit string 12A, a shift amount of a region of the circuit resource to be used generated by the change from the configuration bit string 12 to the changed configuration bit string 12A, and information specifying the region of the circuit resource used by the changed configuration bit string 12A.

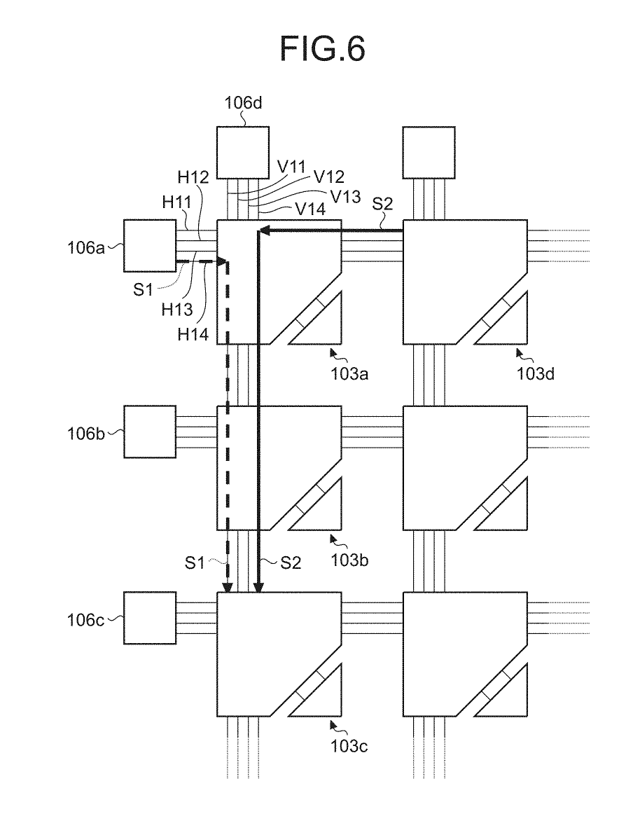

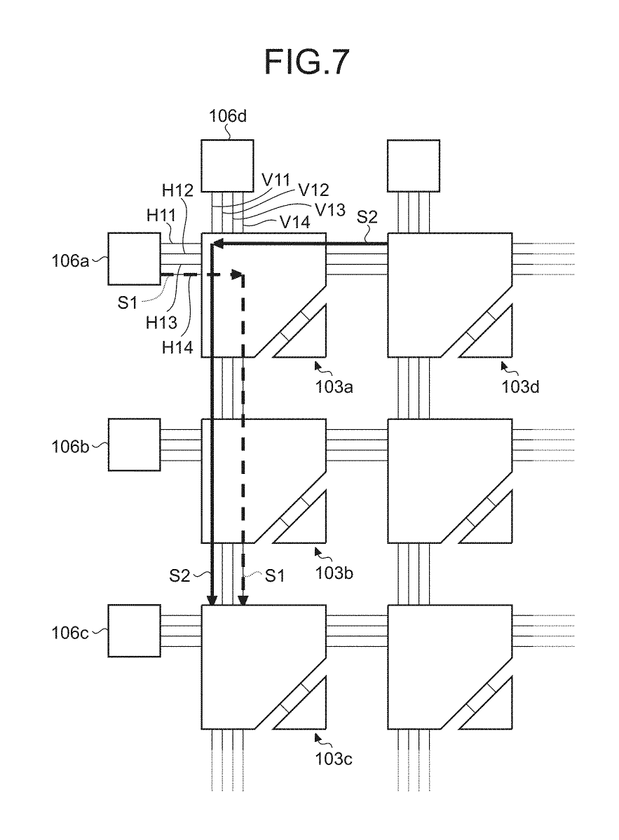

Next, an example of a circuit configuration configured in the circuit group 102 before and after the configuration bit string 12 is changed will be described with reference to FIGS. 6 and 7. FIG. 6 illustrates an example of a circuit configuration implemented in the circuit group in accordance with the non-changed configuration bit string, and FIG. 7 illustrates an example of a circuit configuration implemented in the circuit group in accordance with the changed configuration bit string.

As illustrated in FIG. 6, in a circuit configuration implemented in the circuit group 102 in accordance with the non-change configuration bit string 12, a signal S1 input from an input/output terminal 106a propagates through a wiring H14 and is input to a basic module 103a and then propagates through a wiring V11 and is input to a basic module 103c. A signal S2 from a basic module 103d propagates through a wiring H11 and is input to the basic module 103a and then propagates through a wiring V14 and is input to the basic module 103c. The basic module 103b is assumed to be set in accordance with the configuration bit string 12 to bypass the input signals Si and S2.

On the other hand, as illustrated in FIG. 7, in a circuit configuration implemented in the circuit group 102 in accordance with the changed configuration bit string 12A changed in accordance with a predetermined rule, the signal S1 which propagates through the wiring H14 and is input from the input/output terminal 106a to the basic module 103a propagates through the wiring V14 and is input to the basic module 103c. Further, the signal S2 which propagates through the wiring H11 and is input from the basic module 103d to the basic module 103a propagates through the wiring V11 and is input to the basic module 103c. Similarly to FIG. 6, the basic module 103b is assumed to be set in accordance with the configuration bit string 12 to bypass the input signals S1 and S2.

As described above, since the configuration bit string 12 stored in the configuration memory 101 is changed each time, for example, even when a circuit configuration of executing the same process is implemented in the circuit group 102, a different circuit configuration is implemented in the circuit group 102 each time a new changed configuration bit string 12A is stored in the configuration memory 101. Accordingly, it is possible to prevent the basic module 103 from being intensively used, and thus it is possible to equalize the exhaustion degree in all the basic modules 103 and all the memories connected to the respective basic modules 103. Accordingly, it is possible to improve the product lifespan of FPGA 1.

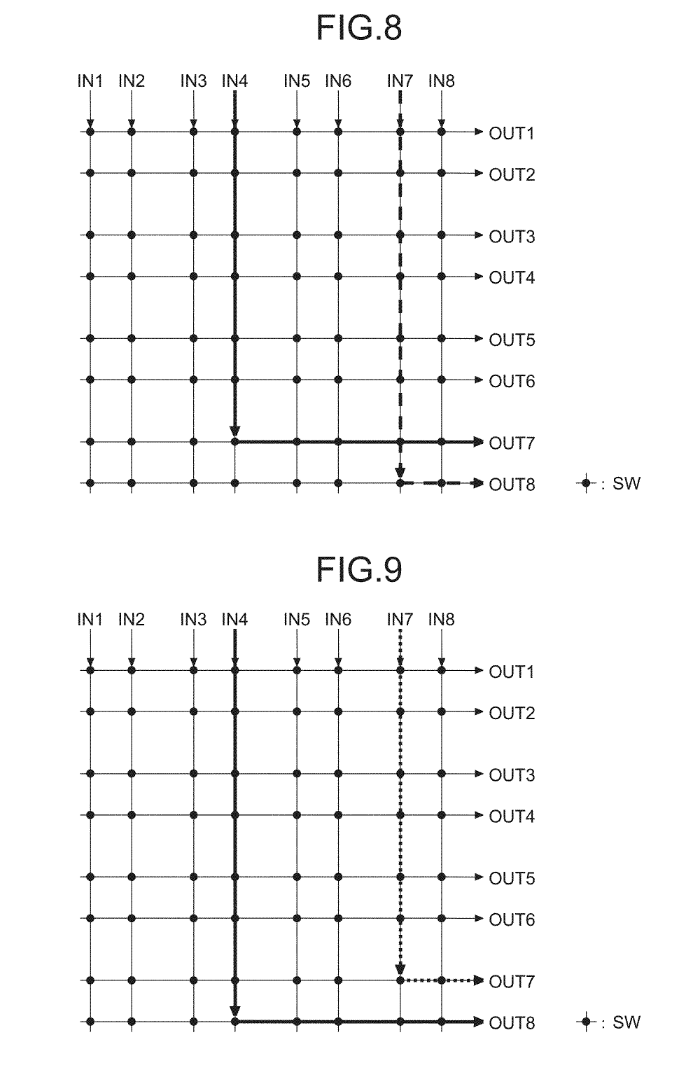

Further, as illustrated in FIGS. 8 and 9, when the bit values in the configuration bit string 12 are changed to control the on/off state of the switch SW in each wiring module 104, the connection paths from the input wirings IN1 to IN8 to the output wirings OUT1 to OUT8 in each wiring module 104 are changed. Even in this case, it is possible to prevent the same wiring from being used intensively, and thus it is possible to equalize the exhaustion degree in all the wirings and all the memories for switching a connection between wirings. Accordingly, it is possible to improve the product lifespan of FPGA 1. FIG. 8 illustrates an example of a connection path formed in the wiring module in accordance with the non-changed configuration bit string, and FIG. 9 illustrates an example of a connection path formed in the wiring module in accordance with the configuration bit string changed in accordance with a certain predetermined rule.

As described above, according to the present embodiment, by appropriately changing the configuration bit string 12 stored in the configuration memory 101, it is possible to change the circuit configuration implemented in the circuit group 102 and the connection path formed in each wiring module 104. Accordingly, even when the circuit configuration of executing the same process is implemented in the circuit group 102, since a different circuit configuration is implemented in the circuit group 102 each time a new changed configuration bit string 12A is stored in the configuration memory 101, it is possible to prevent the same physical module such as the basic module 103 or the wiring from being used intensively. Accordingly, since the exhaustion degree is equalized in all the physical modules and all the memories connected to the respective physical modules, it is possible to improve the product lifespan of the FPGA 1.

The configuration bit changing circuit 111 (see FIG. 5) may be implemented by software or may be implemented by hardware. Further, the present embodiment has been described with the example in which the configuration bit changing circuit 111 is incorporated into the FPGA 1, but the present embodiment is not limited thereto. In other words, for example, the configuration bit string 12 generated by the bit string generating device 301 may be converted into the changed configuration bit string 12A by the configuration bit changing circuit 111 installed outside the FPGA 1, then input to the FPGA 1, and stored in the configuration memory 101.

### Second Embodiment

Next, a second embodiment will be described in detail with reference to the appended drawings. The present embodiment will be described with an example in which the wiring resource connecting the circuit resources are changed without changing the circuit resource to be used in the change from the configuration bit string 12 to the changed configuration bit string 12A.

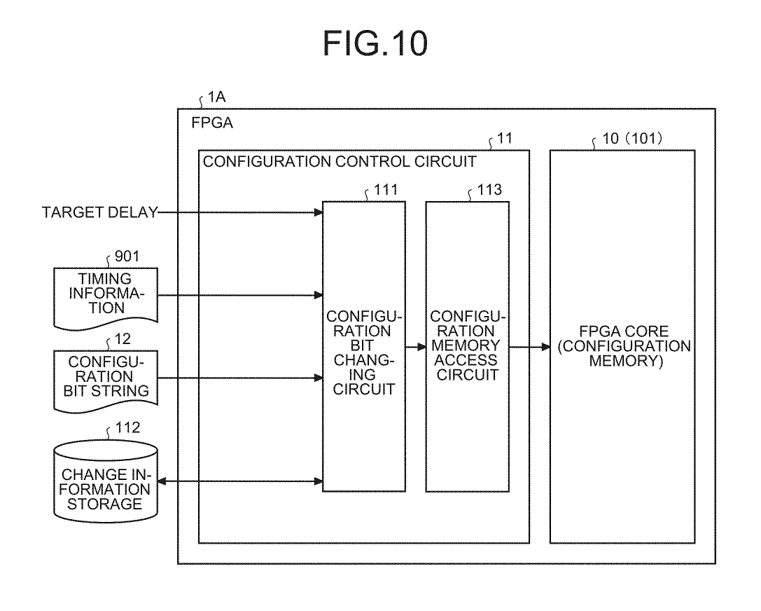

FIG. 10 is a block diagram illustrating a schematic configuration example of the FPGA according to the present embodiment. As illustrated in FIG. 10, an FPGA 1A has a similar configuration to that of the FPGA 1 according to the first embodiment (see FIG. 5 and the like), timing information 901 is input to the configuration bit changing circuit 111, and a target delay is set in the configuration bit changing circuit 111.

Here, the timing information 901 is timing information of each circuit resource such as an input/output timing of a signal required by each basic module 103 included in the circuit configuration implemented in the circuit group 102 in accordance with, for example, the changed configuration bit string 12A. In the present description, as described above, in the change from the configuration bit string 12 to the changed configuration bit string 12A, the basic module 103 to be used is not changed. Therefore, it is possible to calculate the timing information 901 in advance on the basis of the use circuit resource.

Further, the target delay is, for example, a maximum value of an allowable time for the signal delay of each circuit resource. Similarly to the timing information 901, the target delay can be calculated in advance, for example, on the basis of the use circuit resource.

The configuration bit changing circuit 111 generates the changed configuration bit string 12A by changing the input configuration bit string 12 randomly or in accordance with a predetermined rule. Further, the configuration bit changing circuit 111 determines whether or not the circuit configuration implemented by the changed configuration bit string 12A normally operates on the basis of the input timing information 901 and repeatedly changes the configuration bit string 12 or the changed configuration bit string 12A until the normally operating circuit configuration is obtained. The, when the changed configuration bit string 12A implementing the normally operating circuit configuration is obtained, the configuration bit changing circuit 111 stores the changed configuration bit string 12A in the configuration memory 101 via the configuration memory access circuit 113.

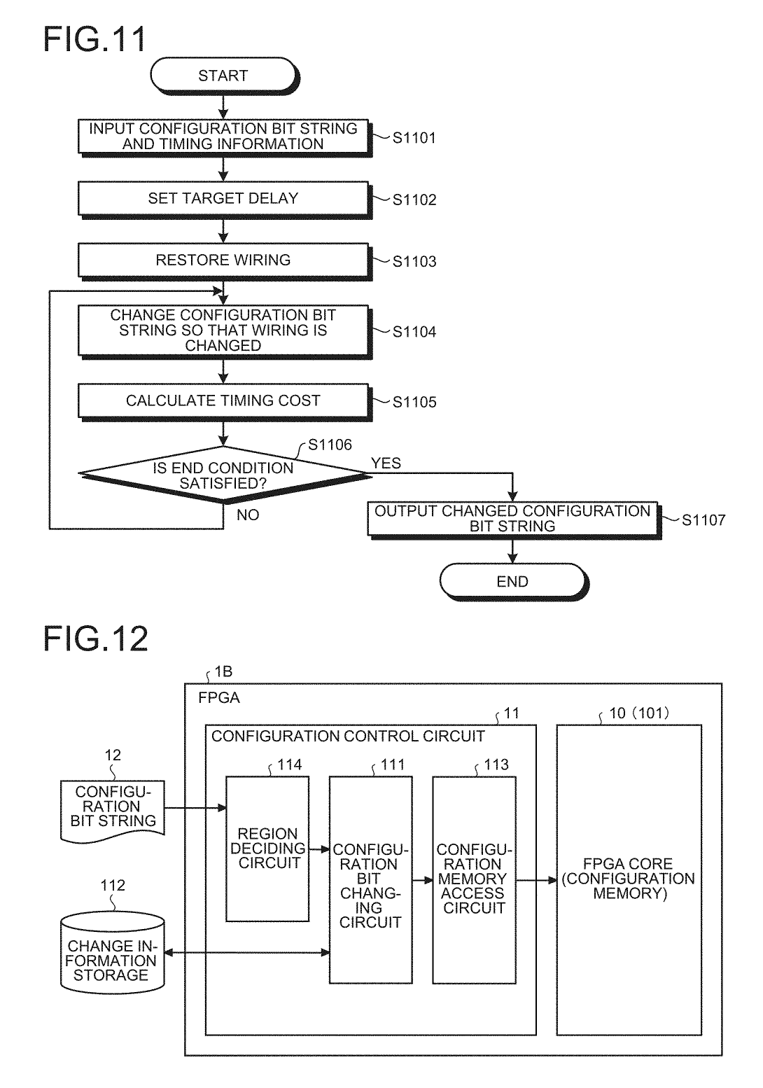

Next, a configuration bit changing operation executed by the configuration control circuit 11 in the present embodiment will be described. FIG. 11 is a flowchart illustrating an example of the configuration bit changing operation in the present embodiment.

As illustrated in FIG. 11, in the present embodiment, the configuration bit string 12 and the timing information are first input to the configuration bit changing circuit 111 of the configuration control circuit 11 (Step S1101). Further, the target delay is set in the configuration bit changing circuit 111 (Step S1102). In the present embodiment, the configuration bit string 12 may be, for example, the configuration bit string 12 calculated by the bit string generating device 301 or may be an existing configuration bit string 12 previously used to implement the same circuit configuration. Further, the timing information 901 may be timing information which the bit string generating device 301 (see FIG. 3) calculates in advance on the basis of the basic module 103 incorporated into the circuit configuration in accordance with the configuration bit string 12.

Then, the configuration bit changing circuit 111 restores the wiring path in the desired circuit configuration on the basis of the input configuration bit string 12 (Step S1103).

Then, the configuration bit changing circuit 111 changes the configuration bit string 12 (or the changed configuration bit string 12A) randomly or in accordance with a predetermined rule (Step S1104) so that the wiring path, that is, the wiring resource to be used is changed. In this case, similarly in the first embodiment, in order to prevent the signal collision, a restriction that a plurality of switch SWs are not turned on in an output line (for example, corresponding to the output wirings OUT1 to OUT8 in FIG. 2) in an overlapping manner may be set in a predetermined rule. Here, in the present embodiment, the restriction that output directions of signals from the respective basic modules 103 (for example, corresponding to the up, down, left, and right direction with respect to each basic module 103 in FIG. 1) does not change in order to prevent a significant change in a signal delay may be omitted. This is because, in the present embodiment, it is possible to prevent the occurrence of a significant signal delay by imposing an end condition based on a timing cost to be described later (see Step S1106).

Then, the configuration bit changing circuit 111 calculates the timing cost in the wiring after the change using the timing information input in Step S1101 (Step S1105). The timing cost is a time cost required for inputting and outputting signals to each basic module 103 and corresponds to the signal delay.

Then, the configuration bit changing circuit 111 determines whether or not a condition (hereinafter referred to as “end condition”) for ending the change of the configuration bit string 12 (or the changed configuration bit string 12A) is satisfied (Step S1106), and when the end condition is satisfied (Step S1106; YES), the configuration bit changing circuit 111 outputs the changed configuration bit string 12, that is, the changed configuration bit string 12A to the configuration memory access circuit 113 (Step S1107), and ends the present operation. As the end condition, for example, a condition that the signal delay obtained from the timing cost calculated in Step S1105 satisfies the target delay set in Step S1102 may be used.

On the other hand, when the end condition is not satisfied (NO in Step S1106), the configuration bit changing circuit 111 returns to Step S1104, and repeats the subsequent operations until the end condition is satisfied.

As described above, in the present embodiment, the calculation of the timing cost is executed in the process of changing the wiring path, and it is determined whether or not the wiring change is possible on the basis of the obtained timing cost. Accordingly, in the present embodiment, it is possible to guarantee the timing of the signal in the circuit configuration implemented in the circuit group 102.

Further, in the present embodiment, it is possible to improve the degree of freedom for the wiring change, and thus it is possible to equalize the exhaustion degree in all the physical modules and all the memories associated with the respective physical modules. As a result, it is possible to further improve the product lifespan of the FPGA 1A.

The configuration bit changing circuit 111 in the present embodiment may be implemented by software or may be implemented by hardware, similarly to the first embodiment. Further, in the present embodiment, the example in which the configuration bit changing circuit 111 is incorporated into the FPGA 1A has been described, but the present embodiment is not limited thereto. In other words, for example, the configuration bit string 12 generated by the bit string generating device 301 may be converted into the changed configuration bit string 12A through the configuration bit changing circuit 111 installed outside the FPGA 1A, then input to the FPGA 1A, and stored in the configuration memory 101 Good.

The remaining components, operations, and effects are similar to those in the above-described embodiment, and thus detailed description is omitted here.

### Third Embodiment

Next, a third embodiment will be described in detail with reference to the appended drawings. The present embodiment will be described with an example in which a region of the circuit resource to be used (hereinafter referred to as “use circuit resource”) is changed to another region in the change from the configuration bit string 12 to the changed configuration bit string 12A.

FIG. 12 is a block diagram illustrating a schematic configuration example of an FPGA in accordance with the third embodiment. As illustrated in FIG. 12, an FPGA 1B has a configuration in which the configuration control circuit 11 further includes a region deciding circuit 114 in addition to a configuration similar to that of the FPGA 1 according to the first embodiment (see FIG. 5 and the like).

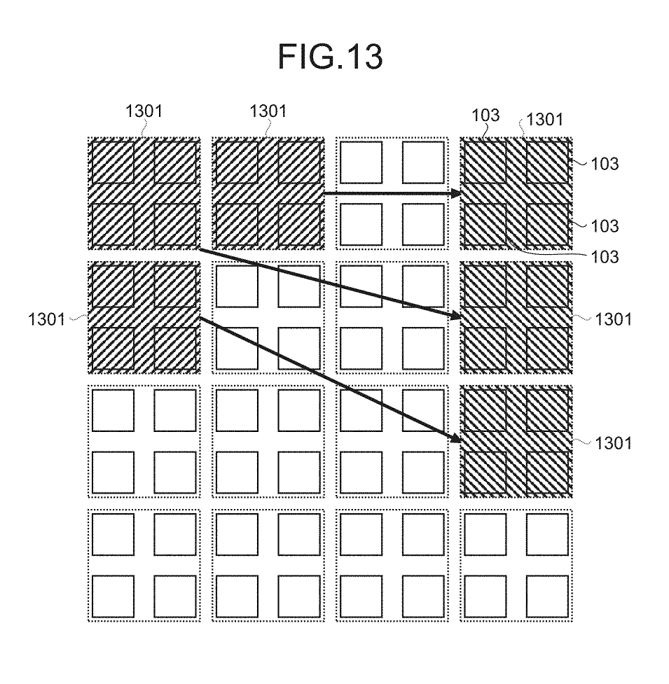

The region deciding circuit 114 specifies the region of the use circuit resource on the basis of a position of the basic module 103 designated by the input configuration bit string 12, shifts the designated region to another region randomly or in accordance with a predetermined rule, and decides a region of the use circuit resource after the change. The region after the change can be deciding by rotating an arrangement or the like in which one or more wiring modules 104 and/or one or more operation modules 105 included in the use circuit resource are used as a unit. Alternatively, as illustrated in FIG. 13, the region deciding circuit 114 may divide the circuit group 102 into a plurality of partial regions 1301 in advance and manages the circuit group 102, and the configuration bit changing circuit 111 may decide the partial region 1301 of the use circuit resource after the change using the partial regions 1301 as a unit randomly or in accordance with a predetermined rule. In this case, the connection relation between the partial regions 1301 is changed, but the connection relation within each partial region 1301 may be maintained. In FIG. 13, the movement of the partial region 1301 according to the change from the configuration bit string 12 to the changed configuration bit string 12A is indicated by an arrow. In FIG. 13, all the partial regions 1301 have the same size (2×2), but the present embodiment is not limited thereto, and the individual partial regions 1301 may have different sizes.

Further, the region deciding circuit 114 inputs information indicating the decided region (hereinafter referred to as “region information”) to the configuration bit changing circuit 111 together with the configuration bit string 12. For example, when the region is a rectangle, the region information may be information specifying the basic modules 103 at the four corners of the region. At this time, as the information specifying the individual basic modules 103, various pieces of information capable of uniquely identifying the basic module 103 such as identification information set for each of the basic modules 103 and address information on the basic module 103 can be used.

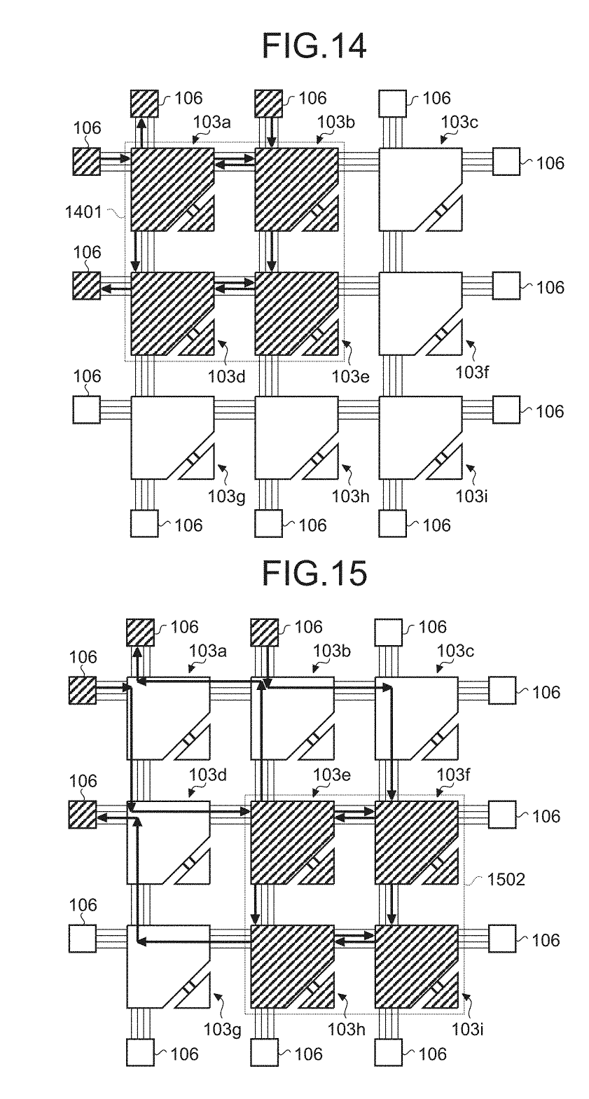

Here, the flow of changing the region of the use circuit resource to another region will be described with reference to FIGS. 14 and 15. FIG. 14 is a diagram illustrating an example of the region of the use circuit resource before the change, and FIG. 15 is a diagram illustrating an example of the region of the use circuit resource after the change. In FIG. 14 and FIG. 15, for the sake of simplicity of description, the description will proceed with an example in which the circuit group 102 includes 3×3 basic modules 103, that is, a total of nine basic modules.

As illustrated in FIG. 14, in the configuration bit string 12, a rectangular region 1401 including 2×2 basic modules, that is, a total of four basic modules 103a, 103b, 103d, and 103e located on the upper left side in FIG. 14 is set as the use circuit resource. On the other hand, as illustrated in FIG. 15, in the changed configuration bit string 12A, a rectangular region 1502 including 2×2 basic modules, that is, a total of four basic modules 103e, 103f, 103h, and 103i located on the lower right side in FIG. 15 is set as the use circuit resource. In other words, in the conversion from the configuration bit string 12 to the changed configuration bit string 12A, the use circuit resource of the region 1401 is shifted to the region 1502 without change.

The connection relation of the basic modules 103a, 103b, 103d, and 103e in the region 1401 may be maintained in the region 1502. In this case, the signal input and output wirings for the use circuit resource of the region 1401 are inherited to the use circuit resource of the region 1502. The basic module 103a in the region 1401 corresponds to the basic module 103e in the region 1502, the basic module 103b in the region 1401 corresponds to the basic module 103f in the region 1502, the basic module 103d in the region 1401 corresponds to the basic module 103h in the region 1502, and the basic module 103e in the region 1401 corresponds to the basic module 103i in the region 1502.

Further, as illustrated in FIGS. 14 and 15, in the conversion from the configuration bit string 12 to the changed configuration bit string 12A, the wiring path connecting the input/output terminal 106 with the basic module 103 in the region 1502 is also changed.

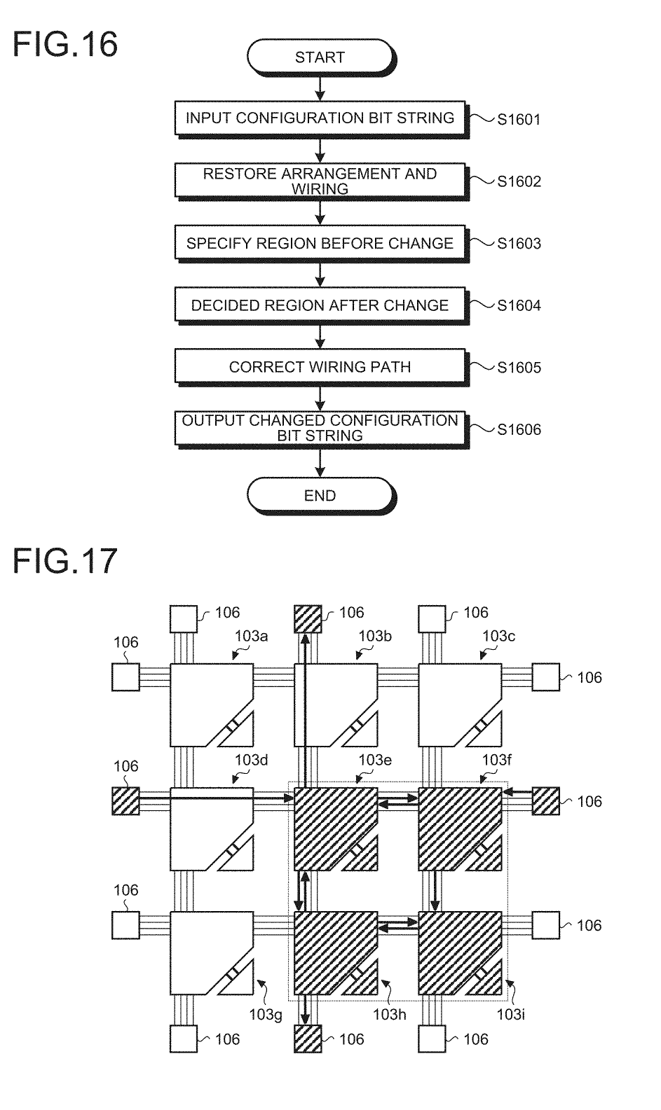

Next, a configuration bit changing operation executed by the configuration control circuit 11 in the present embodiment will be described. FIG. 16 is a flowchart illustrating an example of the configuration bit changing operation in the present embodiment.

As illustrated in FIG. 16, in the present embodiment, the configuration bit string 12 is first input to the region deciding circuit 114 of the configuration control circuit 11 (Step S1601). In the present embodiment, the configuration bit string 12 may be, for example, the configuration bit string 12 calculated by the bit string generating device 301 or may be an existing configuration bit string 12 previously used to implement the same circuit configuration.

Then, the region deciding circuit 114 restores an arrangement of the basic modules 103 and the wirings in the desired circuit configuration from the input configuration bit string 12, for example, in a memory (not illustrated) (Step S1602).

Then, the region deciding circuit 114 specifies the region of the use circuit resource before the change from the arrangement of the basic modules 103 (Step S1603). Then, the region deciding circuit 114 shifts the specified region to another region randomly or in accordance with a predetermined rule and decides the region of the changed use circuit resource (Step S1604). The region information related to the decided region is input to the configuration bit changing circuit 111 together with the configuration bit string 12.

Then, on the basis of the input region information and the configuration bit string 12, the configuration bit changing circuit 111 corrects the wiring path so that the use circuit resource after the region change operates normally (Step S1605). The connection relation in the use circuit resource may be maintained before and after the region change. In this case, in Step S1605, the configuration bit changing circuit 111 corrects the wiring path connecting the input/output terminal 106 used in the configuration bit string 12 with the use circuit resource and generates the changed configuration bit string 12A.

Thereafter, the configuration bit changing circuit 111 outputs the changed configuration bit string 12A for implementing the circuit configuration after the wiring path correction to the configuration memory access circuit 113 (Step S1606), and ends the present operation.

As described above, in the present embodiment, the frequency of use of each circuit resource is equalized by changing the region of use circuit resource, and thus it is possible to improve the product lifespan of FPGA 1B.

The region deciding circuit 114 and the configuration bit changing circuit 111 in the present embodiment may be implemented by software or may be implemented by hardware, similarly to the above-described embodiment. Further, the present embodiment has been described with the example in which the region deciding circuit 114 and the configuration bit changing circuit 111 are incorporated into the FPGA 1B, but the present embodiment is not limited thereto. In other words, for example, the configuration bit string 12 generated by the bit string generating device 301 may be converted into the changed configuration bit string 12A by the region deciding circuit 114 and the configuration bit changing circuit 111 installed outside the FPGA 1B, then input to the FPGA 1B, and stored in the configuration memory 101.

In the above description, the example in which the input/output terminal 106 to be used is not changed in order to supporting the connection restrictions with an external module has been described, but the present embodiment is not limited to such a case. For example, as illustrated in FIG. 17, some or all of the input/output terminals 106 used before the change may be changed to other input/output terminals 106.

The remaining components, operations, and effects are similar to those in the above-described embodiment, and thus detailed description is omitted here.

### Fourth Embodiment

Next, a fourth embodiment will be described in detail with reference to the appended drawings. In the first to third embodiments described above, the configuration bit string 12 is input to the configuration control circuit 11 from the outside. On the other hand, the fourth embodiment will be described with an example in which the changed configuration bit string 12A stored in the configuration memory 101 inside the FPGA is used as the configuration bit string 12 to be changed.

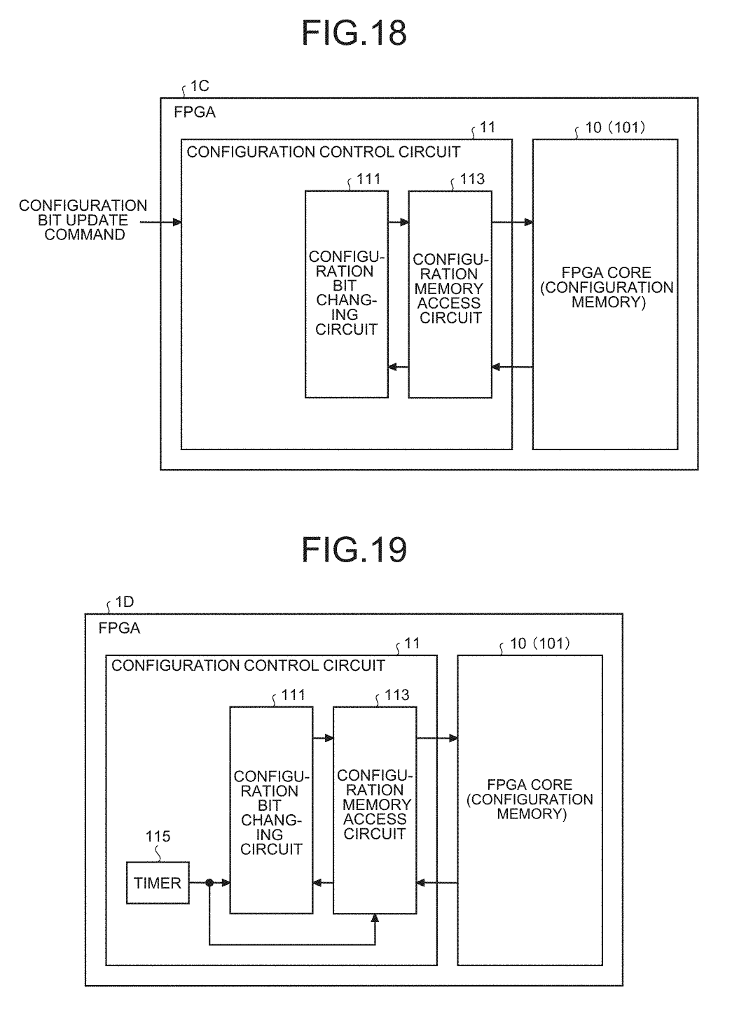

FIG. 18 is a block diagram illustrating a schematic configuration example of the FPGA in accordance with the fourth embodiment. As illustrated in FIG. 18, the FPGA 1C has a configuration in which a configuration bit update command is input to the configuration control circuit 11, and the configuration memory access circuit 113 reads the changed configuration bit string 12A from the configuration memory 101 in the FPGA core 10 and inputs the changed configuration bit string 12A to the configuration bit changing circuit 111 in the configuration similar to the FPGA 1 according to the first embodiment (see FIG. 5 or the like).

When the configuration bit update command is input from an external device such as a PC, for example, the configuration control circuit 11 instructs the configuration memory access circuit 113 to read the changed configuration bit string 12A from the configuration memory 101. The changed configuration bit string 12A read by the configuration memory access circuit 113 is input to the configuration bit changing circuit 111. The configuration bit changing circuit 111 sets the input changed configuration bit string 12A as the configuration bit string 12 to be changed and executes the configuration bit changing operation described in one of the above embodiments on the changed configuration bit string 12A. The changed configuration bit string 12A newly generated as described above is stored in the configuration memory 101 via the configuration memory access circuit 113.

With the above configuration, according to the present embodiment, since a further change is made on the basis of the changed configuration bit string 12A changed in the past, a configuration of accumulating the previous change information can be omitted.

The configuration bit changing circuit 111 in the present embodiment may be implemented by software or may be implemented by hardware, similarly to the above-described embodiments. Further, the present embodiment has been described with the example in which the configuration bit changing circuit 111 is incorporated into the FPGA 1C, but the present embodiment is not limited thereto. In other words, for example, the changed configuration bit string 12A read from the configuration memory 101 may be converted into a new changed configuration bit string 12A by the configuration bit changing circuit 111 installed outside the FPGA 1C, then returned to the FPGA 1C, and stored in the configuration memory 101.

The present embodiment has been described with the example in which the changed configuration bit string 12A in the configuration memory 101 is updated using the input of the configuration bit change command from an external PC or the like as a trigger, but as illustrated in an FPGA 1D in FIG. 19, for example, a timer 115 may be installed in the configuration control circuit 11 so that the changed configuration bit string 12A in the configuration memory 101 is updated using a signal output by the timer 115 with a predetermined period as a trigger. In this case, it is possible to omit control from the outside of the FPGA 1D and implement the FPGA 1D which operates so that the product lifespan is automatically improved. Further, it is possible to remove the bit errors caused by a software error and retention by employing a configuration in which the update is periodically performed. Further, a storage region for separately holding the changed configuration bit string 12A inside the configuration memory 101 is unnecessary.

The remaining components, operations, and effects are similar to those in the above-described embodiment, and thus detailed description is omitted here.

### Fifth Embodiment

In a fifth embodiment, the product lifespan of the FPGA is improved by equalizing the exhaustion degree of the memory cells associated with the respective physical modules of the FPGA. In this regard, in the present embodiment, when the circuit information to be written in the FPGA is decided, that is, at the stage at which the configuration bit string 12 is generated, the exhaustion degree of each memory is specified, and the circuit configuration is decided so that the memory cells with a small exhaustion degree are preferentially used. Accordingly, the imbalance in the exhaustion degree between the memory cells is reduced, and the exhaustion degree is equalized in all the memories, and thus it is possible to improve the product lifespan of the FPGA.

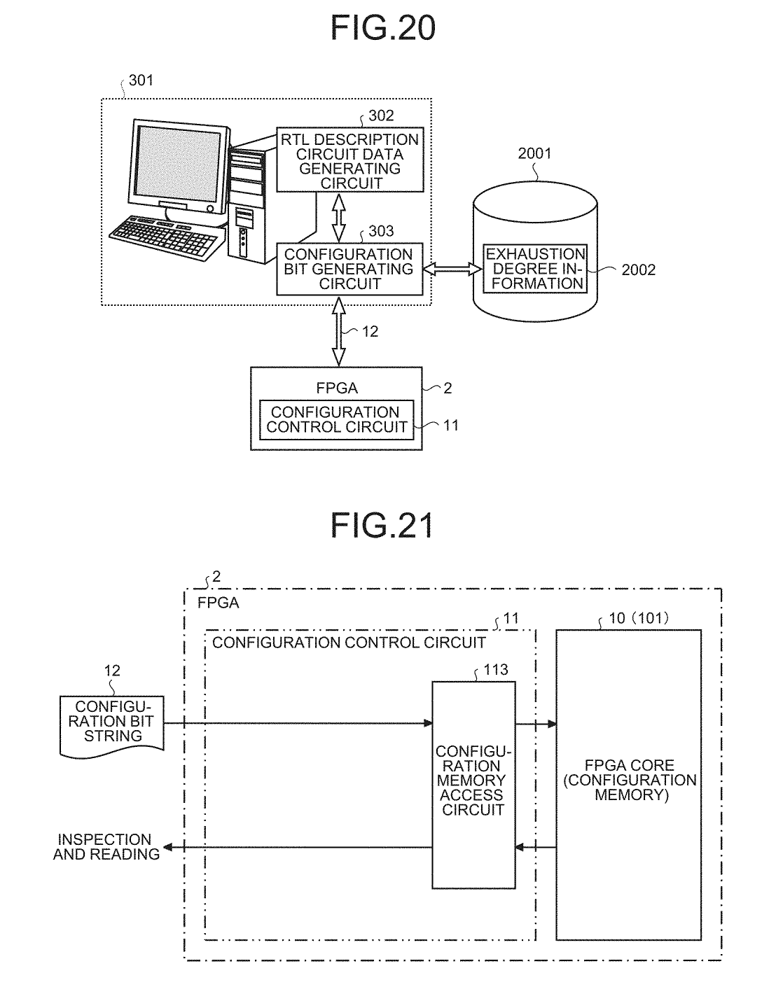

FIG. 20 is a schematic diagram illustrating a schematic configuration example of an external configuration of generating the configuration bit string according to the present embodiment. Further, FIG. 21 is a block diagram illustrating a schematic configuration example of an FPGA according to the present embodiment.

As illustrated in FIG. 20, in the present embodiment, a storage device 2001 that stores information 2002 related to the exhaustion degree of the memory cell (hereinafter referred to as “exhaustion degree information”) is connected to the bit string generating device 301 illustrated in FIG. 3.

For example, the exhaustion degree information is stored in the storage device 2001 for each of the memory cells in the configuration memory 101. Each of the memory cells corresponds to the switch SW in a one-to-one manner (see FIG. 2). Therefore, it is possible to manage the exhaustion degree information for each switch SW by managing the exhaustion degree information for each memory cell. It is also possible to specify exhaustion degree information of a physical module unit by compiling the exhaustion degree information of a group of memory cells corresponding to each wiring module 104 or each operation module 105.

In the exhaustion degree information in the present embodiment, for example, it is possible to use the bit error information obtained by verifying and reading the number of programs/erases and the configuration memory 101 in which one or more memory cells are used as a unit.

The changed configuration bit string 12A stored in the configuration memory 101 is inspected and read at a periodical rewrite timing or the like. Exhaustion degree information 2002 in the storage device 2001 is appropriately updated on the basis of the changed configuration bit string 12A which is inspected and read.

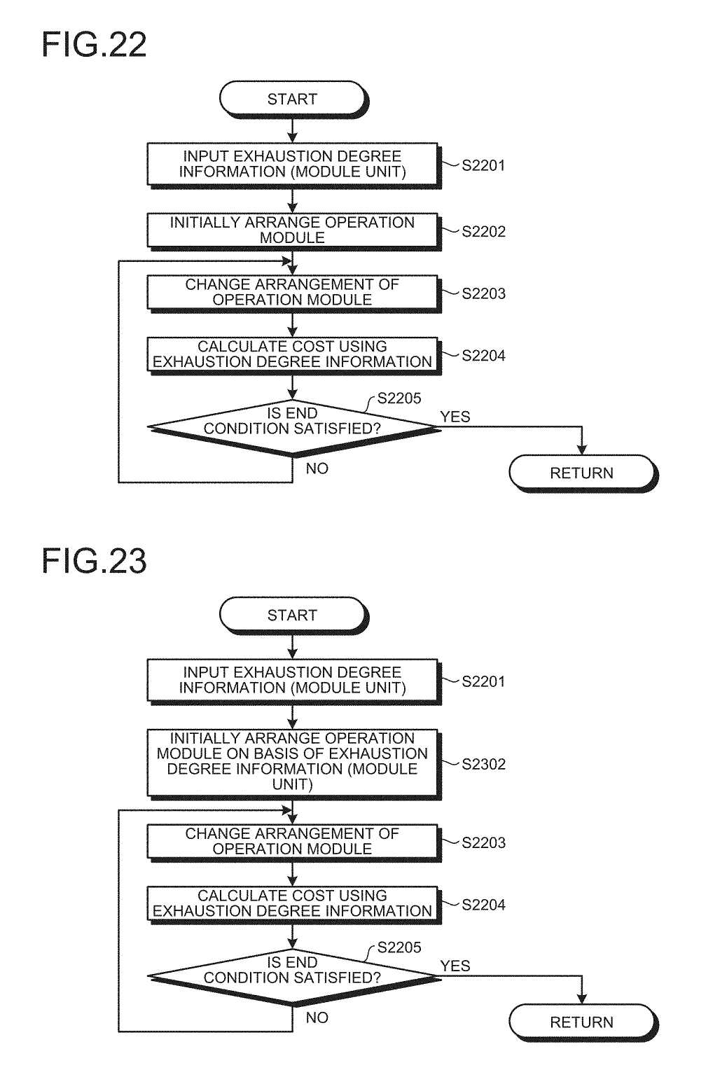

An allocation of the circuit resource based on the exhaustion degree information is executed, for example, in the arrangement process (see Step S404 in FIG. 4) in the EDA flow executed by the configuration bit generating circuit 303. FIG. 22 is a flowchart illustrating a specific example of the arrangement process in the present embodiment.

As illustrated in FIG. 22, the arrangement process in the present embodiment roughly includes of two phases, that is, an initial arrangement of arranging the circuit resource initially and an arrangement change of changing the arrangement of the circuit resource.

Specifically, first, the configuration bit generating circuit 303 acquires the exhaustion degree information of each operation module 105 from the storage device 2001 (Step S2201). Then, the configuration bit generating circuit 303 initially arranges the operation module 105 by randomly allocating, for example, the operation content obtained by the mapping process executed in Step S403 of FIG. 4 to the operation module 105 in the circuit group 102 (Step S2202).

Then, the configuration bit generating circuit 303 arranges the arrangement of the use circuit resource by changing the correspondence relationship between the initially arranged operation content and the operation module 105 randomly or in accordance with a predetermined rule (Step S2203).

Then, the configuration bit generating circuit 303 calculates the cost in the circuit configuration after the arrangement change on the basis of the exhaustion degree information for each operation module 105 input in Step S2201 (Step S2204). The cost can be calculated, for example, using a cost function indicated in the following Formula (1). In Formula (1), A, B, and C are constants for normalization. A timing cost is information of a predicted delay, and a routability cost is information related to the number of wiring connections between the operation modules 105 or a wiring length.

Cost=(A×timing cost)+(B×routability cost)+(C×exhaustion degree information) (1)

As indicated in the cost function of Formula (1), in the present embodiment, in addition to the term of the timing cost and the term of routability cost, the term related to the exhaustion degree is added. As described above, it is possible to preferentially use the operation module 105 corresponding to the memory cell with a small exhaustion degree by considering the exhaustion degree of the memory cell as well when the cost is calculated.

Then, the configuration bit generating circuit 303 determines whether or not the condition for ending the present operation (hereinafter referred to as an “end condition”) is satisfied on the basis of the cost calculated in Step S2204 (Step S2205). For example, the configuration bit generating circuit 303 determines that the end condition is not satisfied when the cost calculated in Step S2204 is larger than a predetermined threshold value (NO in Step S2205), and returns to Step S2203, and repeatedly executes the subsequent operation until the end condition is satisfied. On the other hand, when the end condition is determined to be satisfied (YES in Step S2205), the configuration bit generating circuit 303 returns to, for example, the operation illustrated in FIG. 4.

As described above, by executing the operation illustrated in FIG. 22 in the arrangement process in the EDA flow, the configuration bit string 12 can be generated so that the memory cell with the small exhaustion degree is preferentially used. As illustrated in FIG. 20 and FIG. 21, the generated configuration bit string 12 is input to the configuration control circuit 11 of the FPGA 2 from the bit string generating device 301 (see FIG. 20). The configuration memory access circuit 113 of the configuration control circuit 11 stores the input configuration bit string 12 in the configuration memory 101 of the FPGA core 10.

As described above, according to the present embodiment, the term of the cost related to the exhaustion degree which is obtained from the number of previous uses of the memory cells or the like is added to the objective function (the cost function) used for generating the circuit information. Further, the objective function to which the term considering the exhaustion degree of each memory cell is added is used in the arrangement of the circuit resource. Accordingly, since the arrangement process of the circuit resource is executed in consideration of the exhaustion degree of each memory cell, the frequencies of use of the respective memory cells constituting the configuration memory 101 can be equalized. As a result, since the exhaustion degree is equalized in all the memory cells, the product lifespan of the FPGA 2 is improved.

In the present embodiment, the term considering the exhaustion degree of each memory cell is added to the cost function used in the arrangement process of the circuit resource, but the embodiment is not limited thereto, and for example, the term considering the exhaustion degree of each memory cell may be added to, for example, the objective function (the cost function) used in the wiring phase. In this case, since the wiring process is executed in view of the exhaustion degree of each memory cell, the frequencies of use of the respective memory cells constituting the configuration memory 101 can be equalized similarly. As a result, the exhaustion degree is equalized in all the memory cells, and the product lifespan of FPGA 2 is improved.

The remaining components, operations, and effects are similar to those in the above-described embodiment, and thus detailed description is omitted here.

### Sixth Embodiment

The fifth embodiment has been described with the example in which the operation module 105 is randomly allocated to the operation content obtained by the logic synthesis in the initial arrangement (see Step S402 in FIG. 4) (see Step S2202 in FIG. 22). On the other hand, a sixth embodiment will be described with an example in which the exhaustion degree is considered in the assignment of the operation module 105 to the operation content, that is, an example in which the exhaustion degree is considered in the generation stage of the configuration bit string 12.

In the present embodiment, the bit string generating device that generates the configuration bit string and the FPGA may be similar to, for example, the bit string generating device 301 and the FPGA 2 described in the fifth embodiment (see FIGS. 20 and 21), and thus repeated description is omitted here.

FIG. 23 is a flowchart illustrating a specific example of the arrangement process in the present embodiment. As illustrated in FIG. 23, in the arrangement process in the present embodiment, Step S2202 of FIG. 22 is replaced with Step S2302 of FIG. 23 in the flow similar to that of the arrangement process illustrated in FIG. 22. In the initial arrangement of Step S2302, the configuration bit generating circuit 303 randomly allocates the operation module 105 in the circuit group 102, for example, to the operation content obtained by the mapping process executed in Step S403 of FIG. 4 on the basis of the exhaustion degree information acquired in Step S2201. For example, the configuration bit generating circuit 303 allocates the operation content in order from the operation module 105 having a smaller exhaustion degree.

With the configuration and the operation described above, in the present embodiment, the initial arrangement is performed in order from the operation module 105 having the small exhaustion degree, and thus it is possible to equalize the exhaustion degree of the operation module 105 more efficiently.

The remaining components, operations, and effects are similar to those in the above-described embodiment, and thus detailed description is omitted here.

### Seventh Embodiment

A seventh embodiment will be described with an example in which the initial arrangement is performed using an existing changed configuration bit string 12A instead of the operation content obtained by the mapping process illustrated in Step S403 of FIG. 4.

In the present embodiment, the FPGA may be similar to the FPGA 2 described in the fifth embodiment (see FIG. 21), and thus repeated description is omitted here.

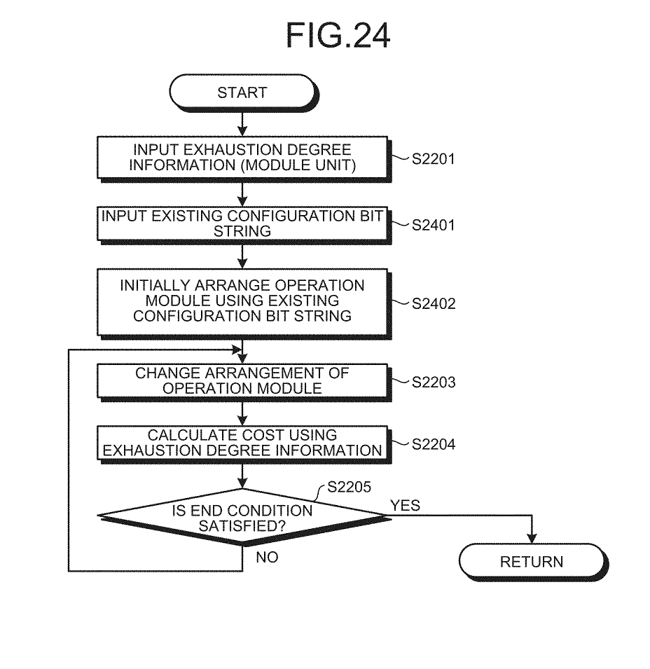

FIG. 24 is a flowchart illustrating a specific example of the arrangement process in the present embodiment. As illustrated in FIG. 24, in the arrangement process o the present embodiment, Step S2202 of FIG. 22 is replaced with Steps S2401 and S2402 of FIG. 24 in the flow similar to that of the arrangement process illustrated in FIG. 22. In Step S2401, the configuration bit generating circuit 303 acquires the changed configuration bit string 12A read from a predetermined storage region (for example, storage device 2001) or the configuration memory 101 of the FPGA 2. For example, an immediately previous or previous changed configuration bit string 12A is assumed to be read from the configuration memory 101 of the FPGA 2 and stocked in the storage device 2001. In Step S2402, the configuration bit generating circuit 303 initially arranges the operation module 105 which is the circuit resource in accordance with the acquired changed configuration bit string 12A.

With the configuration and the operation described above, in the present embodiment, it is possible to initially arrange the operation module 105 on the basis of the changed configuration bit string 12A previously updated in view of the exhaustion degree, and thus it is possible to equalize the exhaustion degree of the memory cell associated with the operation module 105 more efficiently.

Further, in the present embodiment, it is possible to omit, for example, the configuration bit generation operation described with reference to FIG. 4, for example, and thus it is possible to reduce a generation time of the configuration bit string 12 to be input to the FPGA 2.

The remaining components, operations, and effects are similar to those in the above-described embodiment, and thus detailed description is omitted here.

### Eighth Embodiment

The fifth to seventh embodiments has been described with the example in which the exhaustion degree of the memory cell associated with the circuit resource (the operation module 105) is equalized, but an eighth embodiment will be described with an example in which the exhaustion degree of the memory cell associated with the wiring resource is equalized.

In the present embodiment, the bit string generating device that generates the configuration bit string and the FPGA may similar to the bit string generating device 301 and the FPGA 2 described in the fifth embodiment (see FIGS. 20 and 21), and thus repeated description is omitted here.

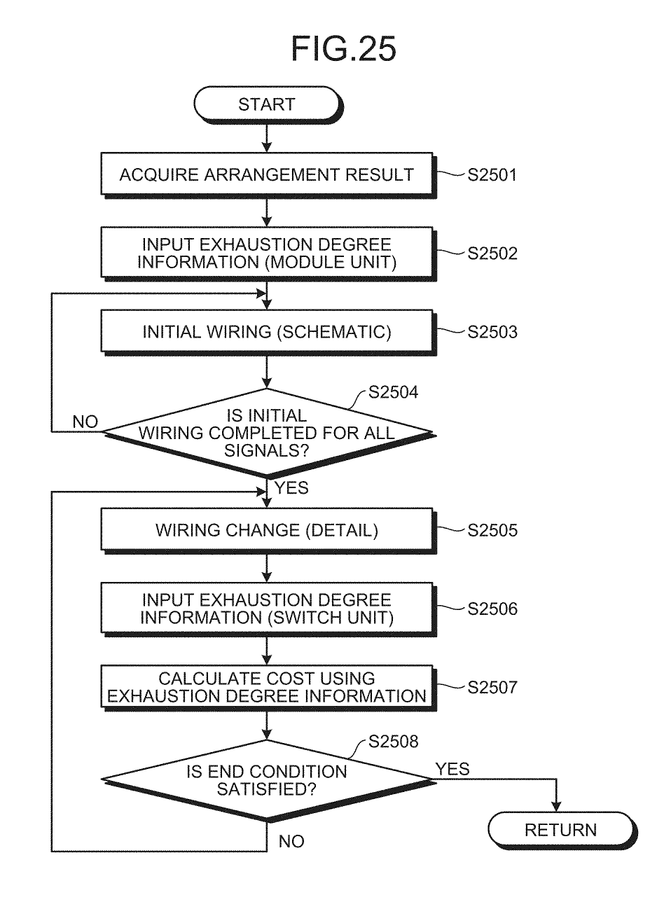

The allocation of the wiring resource on the basis of the exhaustion degree information is carried out, for example, in the wiring process (see Step S405 in FIG. 4) in the EDA flow executed by the configuration bit generating circuit 303. FIG. 25 is a flow chart illustrating a specific example of the wiring process in the present embodiment.

As illustrated in FIG. 25, in the present embodiment, the wiring process is roughly divided into two phases, that is, initial wiring (schematic) of roughly deciding the wiring and wiring change (detail) of changing the wiring and deciding the wiring in detail.

Specifically, first, the configuration bit generating circuit 303 acquires the result of the arrangement process executed in Step S404 of FIG. 4 (Step S2501).

Then, the configuration bit generating circuit 303 acquires the exhaustion degree information of each wiring module 104 from the storage device 2001 (Step S2502), and executes the initial wiring (schematic) of deciding the wiring on the basis of the acquired exhaustion degree information while considering a timing of the wiring path at a wiring module level (Step S2503). In the initial wiring (schematic), the switch SW to be used in the wiring module 104 is not decided. Further, signal collision or wiring congestion (hereinafter referred to as “congestion”) or the like which can occur when a plurality of signals pass through one signal is ignored or allowed. In this case, the cost function when the initial wiring (schematic) in Step S2503 is executed is a cost function in which the term of the routability cost is omitted as indicated in the following Formula (2).

Cost=(A×timing cost)+(C×exhaustion degree information) (2)

The initial wiring (schematic) of Step S2503 is repeatedly executed until the initial wiring is completed for all signals (NO in Step S2504). When the initial wiring is completed for all signals (YES in Step S2504), the configuration bit generating circuit 303 executes the wiring change (detail) (Step S2505). In the wiring change (detail), the switch SW which each signal passes through is decided. Further, when a plurality of signals pass through one wiring, the wiring for the signals is changed.

Then, the configuration bit generating circuit 303 acquires the exhaustion degree information of each switch SW from the storage device 2001 (Step S2506). Then, the configuration bit generating circuit 303 calculates the cost after the wiring change on the basis of the input exhaustion degree information of each switch SW (Step S2507). The cost is calculated, for example, using the cost function indicated in the following Formula (3). In Formula (3), D is a constant for normalization.

Cost=(A×timing cost)+(D×congestion)+(C×exhaustion degree information) (3)

As indicated in the cost function of Formula (3), in the present embodiment, in addition to the term of the timing cost and the term of the congestion, the term related to the exhaustion degree is added. As described above, it is possible to preferentially use the switch SW with a small exhaustion degree by considering the exhaustion degree of the memory cell in the cost calculation.

Then, the configuration bit generating circuit 303 determines whether or not the condition for ending the present operation (hereinafter referred to as an “end condition”) is satisfied on the basis of the cost calculated in Step S2507 (Step S2508). For example, the configuration bit generating circuit 303 determines that the end condition is not satisfied when the cost calculated in Step S2507 is larger than a predetermined threshold value (NO in Step S2508), returns to Step S2505, ends repeatedly executes the subsequent operation until the condition is satisfied. On the other hand, when the end condition is determined to be satisfied (YES in Step S2508), the configuration bit generating circuit 303 returns to, for example, the operation illustrated in FIG. 4.

Thus, in the wiring process of the present process (see Step S405 in FIG. 4), the normalized exhaustion degree information is considered in the respective phases of the initial wiring (schematic) and the wiring change (detail). Here, the exhaustion degree of the wiring module 104 unit is considered in the initial wiring (schematic), and the exhaustion degree of the switch SW unit is considered in the wiring change (detail). With the configuration and the operation described above, it is possible to equalize the exhaustion degree of the memory cell associated with the wiring resource at each level, and thus it is possible to improve the product lifespan of the FPGA.

In the eighth embodiment, the exhaustion degree is considered in the respective phases of the initial wiring (schematic) and the wiring change (detail), but the exhaustion degree may be considered in one of the initial wiring (schematic) and the wiring change (detail). The remaining components, operations, and effects are similar to those in the above-described embodiment, and thus detailed description is omitted here.

### Ninth Embodiment

A ninth embodiment will be described with an example in which the initial wiring (schematic) is performed using an existing changed configuration bit string 12A instead of the arrangement result obtained in the arrangement process illustrated in Step S404 of FIG. 4.

In the present embodiment, the FPGA may be similar to the FPGA 2 described in the fifth embodiment (see FIG. 21), and thus repeated description is omitted here.

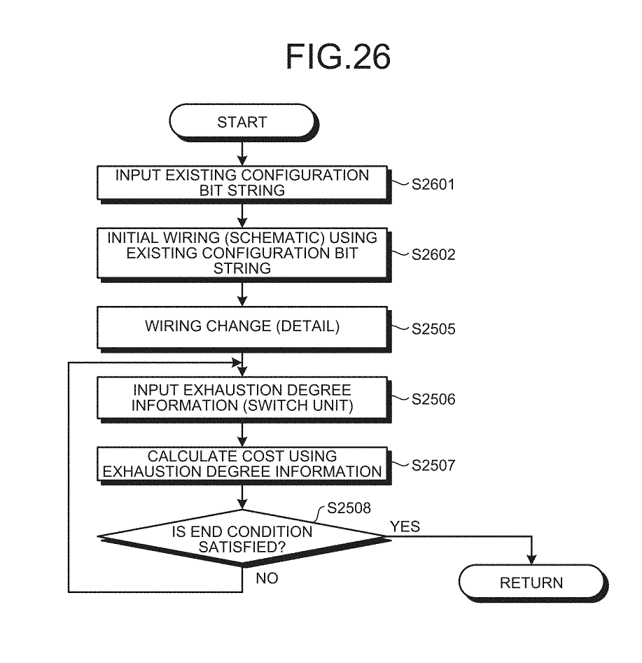

FIG. 26 is a flow chart illustrating a specific example of the wiring process in the present embodiment. As illustrated in FIG. 26, in the wiring process of the present embodiment, Steps S2501 to S2504 of FIG. 25 are replaced with Steps S2601 and S2602 in FIG. 26 in the flow similar to that of the arrangement process illustrated in FIG. 25. In Step S2601, the configuration bit generating circuit 303 acquires the changed configuration bit string 12A read from a predetermined storage region (for example, the storage device 2001) or the configuration memory 101 of the FPGA 2. For example, an immediately previous or previous changed configuration bit string 12A is assumed to be read from the configuration memory 101 of the FPGA 2 and stocked in the storage device 2001. In Step S2602, the configuration bit generating circuit 303 performs an initial arrangement of deciding the wiring path at the wiring module level in accordance with the acquired changed configuration bit string 12A.

With the configuration and the operation described above, in the present embodiment, it is possible to perform the initial wiring on the basis of the changed configuration bit string 12A updated in view of the previous exhaustion degree, and thus it is possible to equalize the exhaustion degree of the memory cell associated with the wiring resource more efficiently.

Further, in the present embodiment, it is possible to omit, for example, the configuration bit generation operation described with reference to FIG. 4, for example, and thus it is possible to reduce a generation time of the configuration bit string 12 to be input to the FPGA 2.

The remaining components, operations, and effects are similar to those in the above-described embodiment, and thus detailed description is omitted here.

### Tenth Embodiment

A tenth embodiment will be described with an example in which a predetermined restriction is set in the wiring change (detail) in the eighth or ninth embodiment (see Step S2505 of FIG. 25 or FIG. 26).

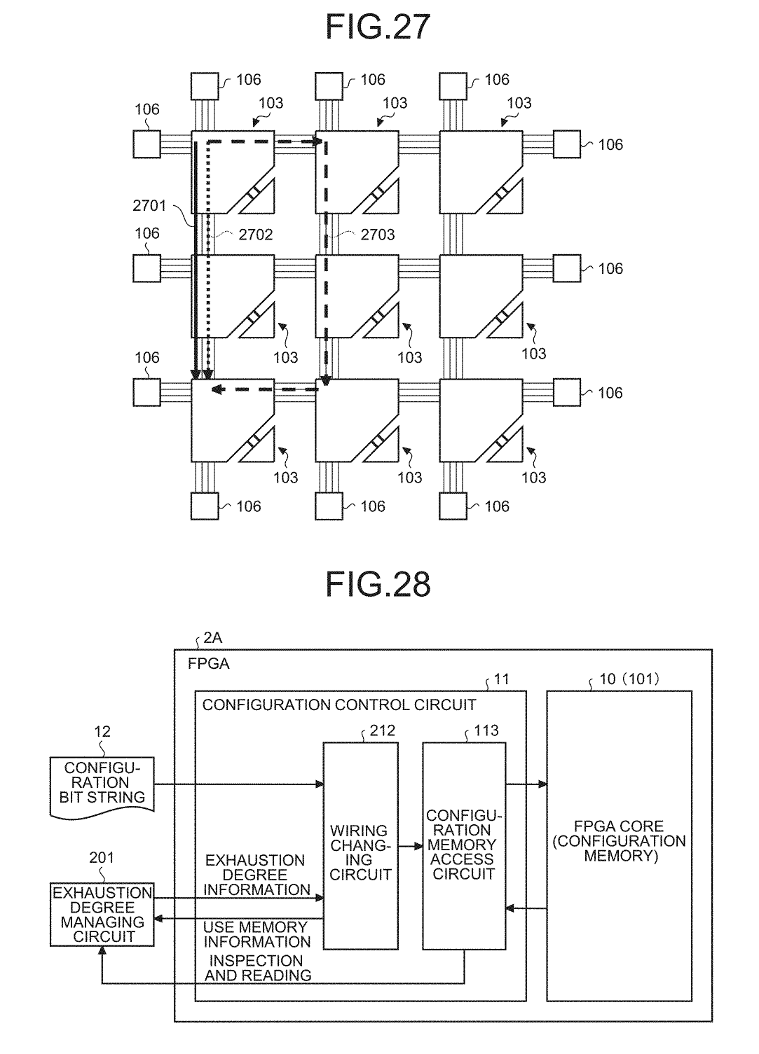

As a predetermined restriction, a restriction that a channel (a bundle of wirings) through which the signal passes is not changed before and after the change may be used. In this case, as illustrated in FIG. 27, it is permitted to change a path 2701 before the change to a path 2702 in the same channel, but it is not allowed to change to a path 2703 using a different channel.

If such a constraint is imposed, the wiring change (detail) of changing the wiring in the same channel is performed, for example in Step S2505 in the eighth or ninth embodiment (see FIG. 25 or 26).

As described above, when a restriction is imposed on the wiring change, it is not necessary to consider a timing guarantee, the wiring congestion, and the like at the time of the wiring change, and thus it is possible to reduce the processing amount and the processing time required for the wiring change. Further, in the cost calculation after the wiring change (see Step S2507 of FIG. 25 or FIG. 26), it is not necessary to consider the timing cost and the congestion, and it is possible to calculate the cost on the basis of the exhaustion degree information, and thus it is possible to easily calculate the cost after the wiring change.

The remaining components, operations, and effects are similar to those in the above-described embodiment, and thus detailed description is omitted here.

### Eleventh Embodiment

The eighth to tenth embodiments has been described with the example in which the configuration bit generating circuit 303 of the bit string generating device 301 executes the wiring change (detail) on the basis of the exhaustion degree, but an eleventh embodiment will be described with an example in which the configuration control circuit 11 in the FPGA executes the wiring change (detail).

FIG. 28 is a block diagram illustrating a schematic configuration example of an FPGA according to the present embodiment. As illustrated in FIG. 28, in an FPGA 2A, for example, in a configuration similar to the FPGA 2 illustrated in FIG. 21, the configuration control circuit 11 further includes a wiring changing circuit 212.

The exhaustion degree information 2002 managed in an external exhaustion degree managing circuit 201 is input to the wiring changing circuit 212. The exhaustion degree managing circuit 201 may be, for example, a storage region reserved in the storage device 2001 or a storage region formed in another storage device. The exhaustion degree information 2002 in the exhaustion degree managing circuit 201 is appropriately updated on the basis of the changed configuration bit string 12A inspected and read out from the configuration memory 101 at a periodic rewriting timing or the like. The changed configuration bit string 12A is generated by executing the wiring process illustrated in FIG. 26 by the wiring changing circuit 212, for example, using the configuration bit string 12 input from the bit string generating device 301 and the exhaustion degree information 2002 input from the exhaustion degree managing circuit 201. Further, the generated changed configuration bit string 12A is stored in the configuration memory 101 of the FPGA core 10 via the configuration memory access circuit 113.

Further, the wiring changing circuit 212 outputs information such as an address specifying the memory cell to be used by the generated changed configuration bit string 12A (hereinafter referred to as “use memory information”) to the exhaustion degree managing circuit 201. The exhaustion degree managing circuit 201 updates the exhaustion degree of the used memory cell (the number of programs/erases or the like) on the basis of the use memory information.

As described above, the configuration of changing the wiring on the basis of the exhaustion degree information 2002 may be incorporated into the FPGA 2A. At this time, when the wiring changing circuit 212 that executes the wiring change (detail) is incorporated into the FPGA 2A as a hardware configuration, it is possible to process the wiring change at a high speed.

The remaining components, operations, and effects are similar to those in the above-described embodiment, and thus detailed description is omitted here.

### Twelfth Embodiment

Further, it is possible to install the configuration of changing the arrangement in the FPGA in addition to the configuration of changing the wiring change (detail).

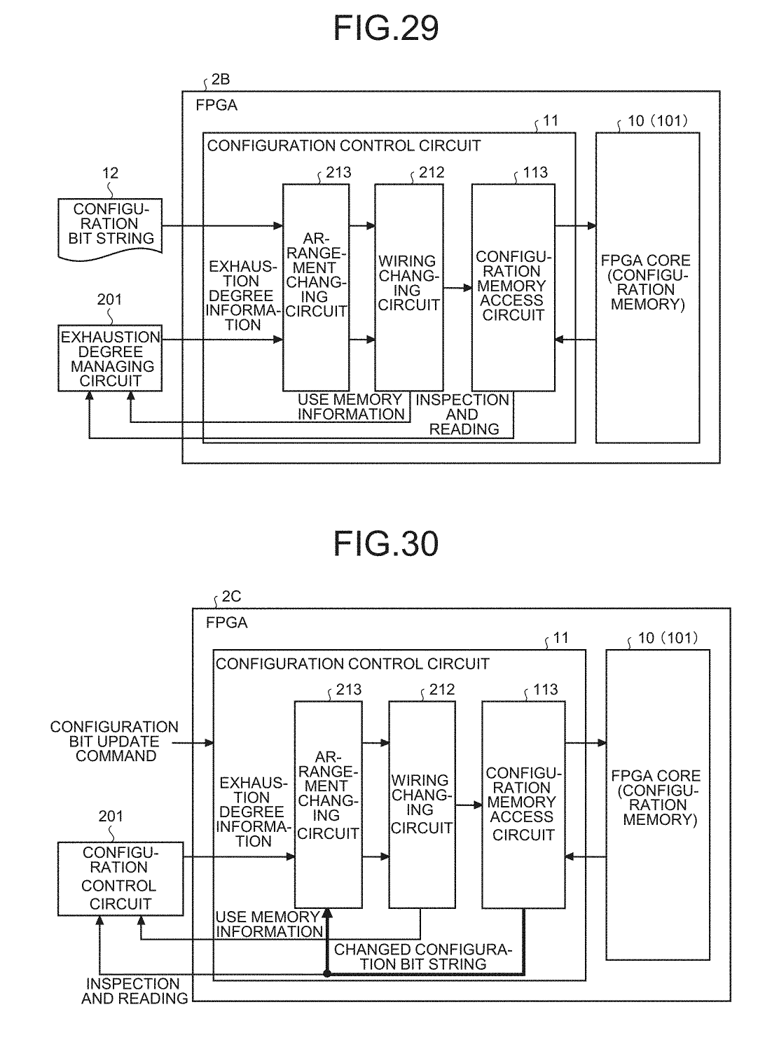

FIG. 29 is a block diagram illustrating a schematic configuration example of an FPGA according to a twelfth embodiment. As illustrated in FIG. 29, in an FPGA 2B according to the present embodiment, for example, in a configuration similar to the FPGA 2A illustrated in FIG. 28, the configuration control circuit 11 further includes an arrangement changing circuit 213.

The exhaustion degree information 2002 managed in the external exhaustion degree managing circuit 201 is input to the arrangement changing circuit 213. The arrangement changing circuit 213 rearranges the circuit resource by executing the arrangement process illustrated in FIG. 24, for example, using the configuration bit string 12 input from the bit string generating device 301 and the exhaustion degree information 2002 read from the exhaustion degree managing circuit 201. Further, the arrangement changing circuit 213 inputs a rearrangement result to the wiring changing circuit 212 together with the exhaustion degree information 2002.

Similarly to the eleventh embodiment, for example, in the wiring changing circuit 212 generates the changed configuration bit string 12A by executing the wiring process illustrated in FIG. 26 using the rearrangement result input from the arrangement changing circuit 213 and the exhaustion degree information 2002. Further, the generated changed configuration bit string 12A is stored in the configuration memory 101 of the FPGA core 10 via the configuration memory access circuit 113.

Similarly to the eleventh embodiment, the wiring changing circuit 212 outputs information such as an address specifying the memory to be used by the generated changed configuration bit string 12A (hereinafter referred to as “use memory information”) to the exhaustion degree managing circuit 201. The exhaustion degree managing circuit 201 updates the exhaustion degree of the used memory cell (the number of programs/erases or the like) on the basis of the use memory information.

As described above, the configuration of changing the arrangement on the basis of the exhaustion degree information 2002 may be incorporated into the FPGA 2B. At this time, when the arrangement changing circuit 213 that executes the arrangement change into the FPGA 2B as a hardware configuration, it is possible to process the arrangement change at a high speed.

The remaining components, operations, and effects are similar to those in the above-described embodiment, and thus detailed description is omitted here.

### Thirteenth Embodiment

The twelfth embodiment has been described with the example in which the rearrangement of the circuit resource and the re-wiring of the wiring resource are executed on the basis of the configuration bit string 12 input from the outside, for example, from the bit string generating device 301, but the rearrangement of the circuit resource and the re-wiring of the wiring resource may be executed, for example, on the basis of the changed configuration bit string 12A stored in the configuration memory 101 of the FPGA core 10.

FIG. 30 is a block diagram illustrating a schematic configuration example of the FPGA in accordance with the thirteenth embodiment. As illustrated in FIG. 30, in an FPGA 2C according to the present embodiment, for example, in a configuration similar to the FPGA 2B illustrated in FIG. 29, the configuration memory access circuit 113 inputs the changed configuration bit string 12A read from the memory 101 to the arrangement changing circuit 213 instead of the configuration bit string 12 input from the outside to the arrangement changing circuit 213. Further, a configuration bit update command indicating a timing to update the changed configuration bit string 12A in the configuration memory 101 is input to the configuration control circuit 11.

When the configuration bit update command is input from an external device such as a PC, for example, the configuration control circuit 11 instructs the configuration memory access circuit 113 to read the changed configuration bit string 12A from the configuration memory 101. The changed configuration bit string 12A read by the configuration memory access circuit 113 is input to the arrangement changing circuit 213. The arrangement changing circuit 213 rearranges the circuit resource by executing the arrangement process illustrated in FIG. 24, for example, using the changed configuration bit string 12A input from the configuration memory access circuit 113 and the exhaustion degree information 2002 read from the exhaustion degree managing circuit 201. Further, the arrangement changing circuit 213 inputs the rearrangement result to the wiring changing circuit 212 together with the exhaustion degree information 2002.

Similarly to, for example, the eleventh embodiment, for example, the wiring changing circuit 212 generates the changed configuration bit string 12A, for example, by executing the wiring process illustrated in FIG. 26 using the rearrangement result input from the arrangement changing circuit 213 and the exhaustion degree information 2002. Further, the generated changed configuration bit string 12A is stored in the configuration memory 101 of the FPGA core 10 via the configuration memory access circuit 113.

With the above configuration, according to the present embodiment, since the further change is made on the basis of the changed configuration bit string 12A which is previously changed, the configuration of accumulating the previous change information can be omitted.

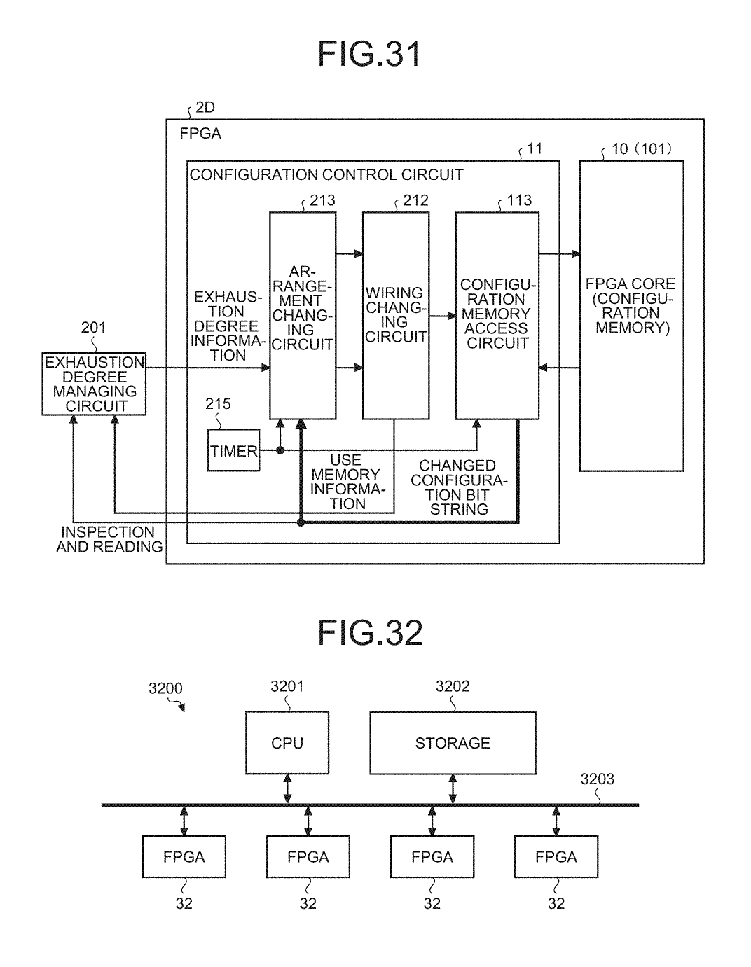

The present embodiment has been described with the example in which the changed configuration bit string 12A in the configuration memory 101 is updated using the input of the configuration bit change command from the external PC or the like as a trigger, but as illustrated in the FPGA 2D of FIG. 31, a timer 215 may be installed in the configuration control circuit 11 so that the changed configuration bit string 12A in the configuration memory 101 is updated using a signal output by the timer 215 with a predetermined period as a trigger. In this case, it is possible to omit control from the outside of the FPGA 2D and implement the FPGA 2D which operates so that the product lifespan is automatically improved. Further, it is possible to remove the bit errors caused by a software error and retention by employing a configuration in which the update is periodically performed. Further, a storage region for separately holding the changed configuration bit string 12A inside the configuration memory 101 is unnecessary.

The remaining components, operations, and effects are similar to those in the above-described embodiment, and thus detailed description is omitted here.

### Fourteenth Embodiment

The first to fourth embodiments have been described with the example in which the exhaustion degrees of the physical resources (the circuit resources and the wiring resources) are equalized by converting the bit array, the bit values, or the like of the configuration bit string 12 (or the changed configuration bit string 12A) randomly or in accordance with a predetermined rule, the fifth to the thirteenth embodiments have been described with the example in which the exhaustion degree is equalized in all the memories by considering the exhaustion degrees of each memory cells, but these embodiments can be combined. In other words, for example, the bit array, the bit values, or the like of the changed configuration bit string 12A generated by considering the exhaustion degree in accordance with any of the fifth to thirteenth embodiments are converted, for example, randomly or in accordance with a predetermined rule in accordance with any one of the first to fourth embodiments. Accordingly, it is possible to equalize the physical resources and the exhaustion degrees of all the memories, and thus it is possible to further improve the product lifespan of the FPGA.

The remaining components, operations, and effects are similar to those in the above-described embodiment, and thus detailed description is omitted here.

### Fifteenth Embodiment

The FPGAs according to the first to the fourteenth embodiments can be incorporated, for example, into a calculation system 3200 in which a plurality of FPGAs 32 and a CPU 3201 are connected via a bus 3203 as illustrated in FIG. 32. In this case, the circuit information for the circuit configuration implemented in each FPGA 32 and the exhaustion degree information in each FPGA 32 may be centrally managed in a storage 3202, and an operation according to any one of the above embodiments may be executed for one or more FPGAs 32 among a plurality of FPGAs 32, and thus it is possible to equalize the physical resources and the exhaustion degrees of all the memories in all a plurality of FPGAs 32.

Further, a control circuit 3201 may perform resource scheduling so that the FPGA 32 with a small exhaustion degree among the FPGAs 32 in a standby state is caused to perform a process preferentially. Accordingly, it is possible to equalize the exhaustion degree in units of the FPGAs 32.

For the update of the exhaustion degree information of each FPGA 32, each FPGA 32 may access the storage 3202 directly and update the exhaustion degree information, or the control circuit 3201 may acquire the use memory information or the like from each FPGA 32 and update the exhaustion degree information in the storage 3202.

As described above, the product lifespan of each FPGA 32 can be further improved by applying the operations description in the first to the fourteenth embodiments to the calculation system 3200 into which a plurality of FPGAs 32 are incorporated.

While certain embodiments have been described, these embodiments have been presented by way of example only, and are not intended to limit the scope of the inventions. Indeed, the novel embodiments described herein may be embodied in a variety of other forms; furthermore, various omissions, substitutions and changes in the form of the embodiments described herein may be made without departing from the spirit of the inventions. The accompanying claims and their equivalents are intended to cover such forms or modifications as would fall within the scope and spirit of the inventions.

What is claimed is:

1. A programmable integrated circuit, comprising:
a circuit group including a plurality of physical modules;
a configuration memory that stores a configuration bit string indicating a physical module to be allocated to each of one or more operation contents in a circuit configuration implemented by the circuit group among the plurality of physical modules;
a changing circuit that changes at least part of the allocation of the physical module to the operation content so that exhaustion degrees of a plurality of memory cells constituting the configuration memory are equalized; and
a configuration memory access circuit that stores a configuration bit string indicating the changed allocation in the configuration memory,
wherein the physical module is associated with any one of the plurality of memory cells in a one-to-one manner,
each bit of the configuration bit string corresponds to any one of the plurality of physical modules in a one-to-one manner, and
each memory cell of the configuration memory stores one bit of the configuration bit string.

2. The programmable integrated circuit according to claim 1, wherein the exhaustion degree includes at least one of the number of programs/erases in which one or more memory cells are used as a unit, the number of uses of each memory cell, and bit error information related to data read from the configuration memory.

3. The programmable integrated circuit according to claim 1, wherein the changing circuit changes the at least part of the allocation of the physical module to the operation content by changing at least some bit values of the configuration bit string indicating the allocation of the physical module to the operation content randomly or in accordance with a predetermined rule.

4. The programmable integrated circuit according to claim 3, wherein the plurality of physical modules include a plurality of wiring modules for switching connection paths with other adjacent physical modules and a plurality of operation modules associated with the respective wiring modules in a one-to-one manner, and
the changing circuit changes the at least some bit values of the configuration bit string so that at least some of the connection paths are changed before and after the change of the configuration bit string.

5. The programmable integrated circuit according to claim 3, wherein, when a signal delay occurring in a circuit configuration implemented in the circuit group in accordance with the changed configuration bit string exceeds a predetermined threshold value, the changing circuit further changes at least some bit values of the changed configuration bit string.

6. The programmable integrated circuit according to claim 3, wherein the plurality of physical modules include a plurality of wiring modules for switching connection paths with other adjacent physical modules and a plurality of operation modules associated with the respective wiring modules in a one-to-one manner,
the programmable integrated circuit further includes a region deciding circuit that decides one or more regions of a plurality of operation modules included in a circuit configuration implemented in the circuit group in accordance with a non-changed configuration bit string among the plurality of operation modules, and
the changing circuit changes the at least some bit values of the configuration bit string so that connection paths between the plurality of operation modules in each of the one or more regions are maintained, and at least one of the one or more regions is moved to another region in the circuit group.

7. The programmable integrated circuit according to claim 3, wherein the configuration memory access circuit reads the configuration bit string stored in the configuration memory and inputs the configuration bit string to the changing circuit, and
the changing circuit changes the at least some bit values of the configuration bit string input from the configuration memory access circuit randomly or in accordance with a predetermined rule.

8. The programmable integrated circuit according to claim 3, further comprising,
a storage that stores content of change executed on the configuration bit string by the changing circuit as change information,
wherein the changing circuit decides the content of the change to be executed on the configuration bit string stored in the configuration memory on the basis of the change information stored in the storage.

9. The programmable integrated circuit according to claim 8, wherein the change information includes at least one of the number of uses of each memory cell in the configuration memory, information specifying the operation module to be used by the changed configuration bit string, a shift amount of a region of an operation module to be used which is caused by the change on the configuration bit string, and information specifying the region of the operation module to be used by the changed configuration bit string.

10. The programmable integrated circuit according to claim 1, further comprising,
a managing circuit that manages the exhaustion degrees of the plurality of memory cells constituting the configuration memory,
wherein the changing circuit change the at least part of the allocation of the physical module to the operation content so that the physical module associated with a memory cell having an exhaustion degree smaller than the exhaustion degrees of other memory cells is preferentially allocated to any one of the one or more operation contents.

11. The programmable integrated circuit according to claim 10, wherein the changing circuit receives the configuration bit string and changes at least some bit values of the configuration bit string so that the physical module associated with a memory cell having an exhaustion degree smaller than the exhaustion degrees of other memory cells is preferentially allocated to any one of the one or more operation contents, and
the configuration memory access circuit reads the configuration bit string stored in the configuration memory and inputs the configuration bit string to the changing circuit.

12. The programmable integrated circuit according to claim 7, wherein the configuration memory access circuit reads the configuration bit string stored in the configuration memory in accordance with an update command input from an outside and inputs the configuration bit string to the changing circuit.

13. The programmable integrated circuit according to claim 11, wherein the configuration memory access circuit reads the configuration bit string stored in the configuration memory in accordance with an update command input from an outside and inputs the configuration bit string to the changing circuit.

14. The programmable integrated circuit according to claim 7, further comprising,
a timer that outputs a signal with a predetermined period,
wherein the configuration memory access circuit reads the configuration bit string stored in the configuration memory using the signal output from the timer as a trigger and inputs the configuration bit string to the configuration bit changing circuit.

15. The programmable integrated circuit according to claim 11, further comprising,
a timer that outputs a signal with a predetermined period,
wherein the configuration memory access circuit reads the configuration bit string stored in the configuration memory using the signal output from the timer as a trigger and inputs the configuration bit string to the configuration bit changing circuit.

16. A calculation system, comprising:
a plurality of programmable integrated circuits cited in claim 1;
a managing circuit that manages an exhaustion degree of the configuration memory in each of the plurality of programmable integrated circuits; and
a control circuit that performs resource scheduling so that the programmable integrated circuit which is smaller in an exhaustion degree managed by the managing circuit among the plurality of programmable integrated circuits is caused to perform a process preferentially.

17. A bit string generating device that generates the configuration bit string to a programmable integrated circuit including a circuit group including a plurality of physical modules, and a configuration memory that stores a configuration bit string indicating a physical module to be allocated to each of one or more operation contents in a circuit configuration implemented by the circuit group among the plurality of physical modules, the physical module being associated with one of a plurality of memory cells constituting the configuration memory in a one-to-one manner, each of bits of the configuration bit string being associated with one of the plurality of physical modules in a one-to-one manner, each memory cell of the configuration memory storing any one bit of the configuration bit string, the bit string generating device, comprising:
a configuration bit generating circuit that changes at least part of the allocation of the physical module to the operation content so that exhaustion degrees of a plurality of memory cells constituting the configuration memory are equalized and outputs a configuration bit string indicating the changed allocation.

18. The bit string generating device according to claim 17, further comprising,
a managing circuit that manages the exhaustion degrees of the plurality of memory cells constituting the configuration memory,
wherein the configuration bit generating circuit change the at least part of the allocation of the physical module to the operation content so that the physical module associated with a memory cell having an exhaustion degree smaller than the exhaustion degrees of other memory cells is preferentially allocated to any one of the one or more operation contents.

19. A control method of a programmable integrated circuit including a circuit group including a plurality of physical modules and a configuration memory that stores a configuration bit string indicating a physical module to be allocated to each of one or more operation contents in a circuit configuration implemented by the circuit group among the plurality of physical modules, the control method comprising:
changing at least part of the allocation of the physical module to the operation content so that exhaustion degrees of a plurality of memory cells constituting the configuration memory are equalized; and
storing a configuration bit string indicating the changed allocation in the configuration memory,
wherein the physical module is associated with any one of the plurality of memory cells in a one-to-one manner, each bit of the configuration bit string corresponds to any one of the plurality of physical modules in a one-to-one manner, and
each memory cell of the configuration memory stores one bit of the configuration bit string.

20. A bit string generation method of generating the configuration bit string to a programmable integrated circuit including a circuit group including a plurality of physical modules, and a configuration memory that stores a configuration bit string indicating a physical module to be allocated to each of one or more operation contents in a circuit configuration implemented by the circuit group among the plurality of physical modules, the physical module being associated with one of a plurality of memory cells constituting the configuration memory in a one-to-one manner, each of bits of the configuration bit string being associated with one of the plurality of physical modules in a one-to-one manner, each memory cell of the configuration memory storing any one bit of the configuration bit string, the bit string generation method, comprising:
changing at least part of the allocation of the physical module to the operation content so that exhaustion degrees of a plurality of memory cells constituting the configuration memory are equalized; and
outputting a configuration bit string indicating the changed allocation.
